(19) United States
(12) Patent Application Publication
(10) Pub. No.: US 2024/0172550 A1
(43) Pub. Date: May 23, 2024

(54) CHARGE-TRANSPORTING COMPOSITION

(71) Applicant: NISSAN CHEMICAL CORPORATION, Tokyo (JP)

(72) Inventors: Shun YAMAGUCHI, Funabashi-shi (JP); Shun SUGAWARA, Funabashi-shi (JP)

(73) Assignee: NISSAN CHEMICAL CORPORATION, Tokyo (JP)

(21) Appl. No.: 18/279,323

(22) PCT Filed: Mar. 23, 2022
(86) PCT No.: PCT/JP2022/013373

§ 371 Date: Aug. 29, 2023

(30) Foreign Application Priority Data
Mar. 26, 2021 (JP) 2021-053355
May 21, 2021 (JP) 2021-086174

(51) Int. Cl. H10K 85/10; C08G 61/12; C08G 65/48; H10K 30/81; H10K 50/15

(52) U.S. Cl. CPC H10K 85/113; C08G 61/126; C08G 65/485; H10K 30/81; H10K 50/15; C08G 2261/3223; C08G 2261/512; C08G 2261/91

(57) ABSTRACT

Provided is a charge-transporting composition for formation of an electrical charge-transporting thin film for use in a photoelectric conversion element, together with a non-fullerene active layer. The charge-transporting composition comprises: a charge-transporting substance composed of a polythiophene derivative containing a repeating unit represented by formula (1); an electron-accepting dopant substance; and a solvent. The electron-accepting dopant substance includes at least one of an arylsulfonic acid represented by formula (2) and a heteropoly acid.

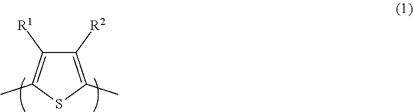

(R¹ and R² are, mutually independently, a hydrogen atom, an alkoxy group, —O—[Z—O]ₚ—R^{e}, a sulphonic acid group, etc. p is an integer of 1 or greater, and R^{e} is a hydrogen atom or an alkyl group, etc. that may be substituted with a sulphonic acid group, or the like.)

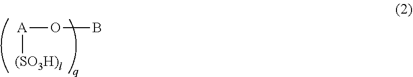

(A is a naphthalene ring, etc.; B is a divalent through tetravalent perfluorobiphenyl group; l is an integer that satisfies 1≤l≥4; and q is an integer of 2-4.)

### TECHNICAL FIELD

The present invention relates to a charge transporting composition. More particularly, the invention relates to a charge transporting composition for forming a charge transporting thin film that can be used together with a non-fullerene acceptor active layer in photovoltaic devices.

### BACKGROUND ART

Electronic devices, especially organic photovoltaic devices, are devices which use an organic semiconductor to convert light energy into electrical energy. An example of such a device is an organic solar cell.

An organic solar cell is a solar cell device that uses an organic compound in an active layer or a charge transporting substance. The dye-sensitized solar cells developed by M. Grätzel and the organic thin-film solar cells developed by C. W. Tang are well known (Non-Patent Documents 1 and 2).

Because both have characteristics differing from the inorganic solar cells that currently predominate, such as the fact that they are thin, lightweight films which can be made flexible, and the fact that roll-to-roll production is possible, they are expected to lead to the creation of new markets.

Also, organic thin-film solar cells, when compared with existing photovoltaic devices that use silicon-based materials, exhibit a high photoelectric conversion efficiency even under low illumination, enable thinner devices and smaller pixels to be achieved, and are able to provide also the attributes of a color filter, making them of interest not only in solar cell applications, but also in image sensor and other photosensor applications (Patent Documents 1 and 2, Non-Patent Document 3). In addition to organic solar cells (dye-sensitized solar cells and organic thin-film solar cells), light sensors and other applications are collectively referred to below as “organic photovoltaic devices” (sometimes abbreviated below as OPVs).

Organic photovoltaic devices are constructed of, for example, an active layer (photoelectric conversion layer), charge (hole, electron) collecting layers and electrodes (anode, cathode). Of these, the role of the hole collecting layer is to extract holes that have formed in the active layer to the electrodes. This can be effectively carried out by making the energy barrier between the active layer and the hole collecting layer small.

Active layers in which a conjugated compound is used as an electron-donating organic material (p-type organic semiconductor) and a fullerene or fullerene derivative is such as a conjugated C₆₀ compound having n-type semiconductor properties is used as an electron-accepting organic material (n-type organic semiconductor) (such an active layer is abbreviated below as a “FA active layer”) have hitherto been used as the active layer in conventional organic photovoltaic devices.

For reasons having to do with, in addition to the above points, the mass-production process, water-dispersible polymeric organic conductive materials such as the coating-type hole collecting layer material PEDOT/PSS are widely used with such FA active layers. For example, Qun Wan et al. have reported a photoelectric conversion efficiency (abbreviated below as “PCE”) of about 11% (Non-Patent Document 4). However, with an FA active layer, not only does the PCE not reach a practically useful level, it sometimes even approaches a theoretical limit, and so active layer development continues to this day.

New materials called non-fullerene acceptors (abbreviated below as “NFAs”), which are neither fullerenes nor fullerene derivatives, have recently been developed as novel n-type organic semiconductors, and NFA active layers using these have been developed. Owing to, for example, an increase in the photoelectric current and a rise in the cell voltage, organic photovoltaic devices containing a NFA active layer exhibit a higher PCE than when a FA active layer is used. In fact, Jianhui Hou et al. have reported a PCE of 18% with the use of a NFA active layer (Non-Patent Document 5).

At the same time, MoO₃, a vapor deposition-type hole collecting layer regarded as unsuitable for mass production, is widely used as the hole collecting layer in these organic photovoltaic devices that exhibit a high PCE. This is because the HOMO-LUMO level of the novel active layer is deeper than that of conventional active layers, and so an energy gap arises with the ionization potential (abbreviated below as “Ip”) of the PEDOT/PSS. Hence, there exists a desire for a coating-type hole collecting material which has a deep Ip to (Non-Patent Document 6),

### PRIOR ART DOCUMENTS

### Patent Documents

Patent Document 1: JP-A 2003-234460
Patent Document 2: JP-A 2008-258474

### Non-Patent Documents

Non-Patent Document 1: Nature, Vol. 353, 737-740 (1991)
Non-Patent Document 2: Appl. Phys. Lett., Vol. 48, 183-185 (1986)
Non-Patent Document 3: Scientific Reports, Vol. 5: 7708, 1-7 (2015)
Non-Patent Document 4: Adv. Funct. Mater., Vol. 26, 6635-6640 (2016)
Non-Patent Document 5: Adv. Mater., Vol. 32, 1908205 (2020)
Non-Patent Document 6: Sol. RRL, 2000749 (2021)

### SUMMARY OF INVENTION

### Technical Problem

The present invention was arrived at in light of the above circumstances. An object of the invention is to provide a charge transporting composition which is suitable for forming a charge transporting thin film that can be used together with a NFA active layer in photovoltaic devices and which, particularly when used as the hole collecting layer in an organic photovoltaic device, further deepens the Ip of the resulting charge transporting thin film, reduces the energy gap with the NFA active layer, and enables the device to achieve a higher voltage.

### Solution to Problem

In the course of intensive investigations aimed at achieving the above object, the inventors have discovered that a charge transporting composition which includes a to polythiophene derivative containing certain repeating units, a specific electron accepting dopant substance and a solvent is suitable for forming a charge transporting thin film in photovoltaic devices having a NFA active layer and, particularly when used as the hole collecting layer in an organic photovoltaic device, further deepens the Ip of the resulting charge transporting thin film, thereby making it possible to decrease the size of the energy gap with the NFA active layer and enabling the device to achieve a higher voltage.

Accordingly, the invention provides the following charge transporting composition.
1. A charge transporting composition for forming a charge transporting thin film in a photovoltaic device having a non-fullerene active layer, which composition includes a charge transporting substance comprised of a polythiophene derivative having repeating units of formula (1) below

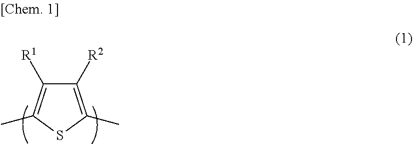

(wherein R¹ and R² are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, an aryloxy group of 6 to 20 carbon atoms, —O—[Z—O]ₚ—R^{e}, a sulfonic group or a sulfonate group, or R¹ and R² are bonded together to form —O—Y—O—; Y is an alkylene group of 1 to 40 carbon atoms which may include an ether bond and may be substituted with a sulfonic group or a sulfonate group; Z is an alkylene group of 1 to 40 carbon atoms which may be substituted with a halogen atom; p is an integer of 1 or more; and R^{e} is a hydrogen atom, an alkyl group of 1 to 40 carbon atoms which may be substituted with a sulfonic group or a sulfonate group, a fluoroalkyl group of to 40 carbon atoms which may be substituted with a sulfonic group or a sulfonate group, or an aryl group of 6 to 20 carbon atoms which may be substituted with a sulfonic group or a sulfonate group), an electron accepting dopant substance and a solvent,
wherein the electron accepting dopant substance includes at least one compound selected from the group consisting of arylsulfonic acids of formula (2) below

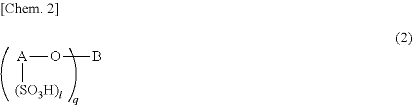

(wherein A is a naphthalene ring or an anthracene ring, B is a perfluorobiphenyl group having a valence of from 2 to 4, the letter is an integer which represents the number of sulfonic groups bonded to A and satisfies the condition 1≤l≤4, and q is an integer from 2 to 4 which represents the number of bonds between B and X) and heteropolyacids.
2. The charge transporting composition of 1 above, wherein the electron accepting dopant substance includes an arylsulfonic acid of formula (2) and a heteropolyacid.
3. The charge transporting composition of 1 or 2, wherein the heteropolyacid includes at least one compound selected from the group consisting of phosphotungstic acid and phosphomolybdic acid.
4. The charge transporting composition of any of 1 to 3 above which further includes a surfactant.
5. The charge transporting composition of 4 above, wherein the surfactant is a fluorinated surfactant.
6. The charge transporting composition of any of 1 to 5 above, wherein the solvent includes one or more solvent selected from the group consisting of alcoholic solvents and water.
7. The charge transporting composition of any of 1 to 6 above for use as a hole collecting layer in an organic photovoltaic device.
8. The charge transporting composition of 7 above, wherein the organic photovoltaic device is an organic thin-film solar cell, a dye-sensitized solar cell or a photosensor.
9. A charge transporting thin film obtained from the charge transporting composition of any of 1 to 6 above.
10. The charge transporting thin film of 9 which is a hole collecting layer for an organic photovoltaic device.
11. An electronic device which includes the charge transporting thin film of 9 or 10 above.
12. The electronic device of 11 above which is an organic photovoltaic device.
13. An organic photovoltaic device which includes the hole collecting layer of 10 above and a non-fullerene active layer provided adjacent thereto.
14. The organic photovoltaic device of 13 above, wherein the non-fullerene active layer includes a polymer having a thiophene skeleton on the main chain.
15. The organic photovoltaic device of 13 or 14 above which is an inverted stack-type device.
16. The organic photovoltaic device of any of 13 to 15 above which is an organic thin-film solar cell or a photosensor.
17. The organic photovoltaic device of 16 above which has a top anode structure.

### Advantageous Effects of Invention

Not only is it possible to prepare the inventive charge transporting composition for an organic photovoltaic device using a charge transporting substance composed of a polythiophene derivative that is commercially available at low cost or can be easily synthesized by a known method, in cases where a thin film obtained from the inventive composition is used in particular as a hole collecting layer in a photovoltaic device having a NFA active layer, when the thin film is used as the hole collecting layer in an organic photovoltaic device, the Ip of the resulting charge transporting thin film is further deepened, enabling the energy gap with the NFA active layer to be made smaller and thus achieving a higher device voltage.

### DESCRIPTION OF EMBODIMENTS

The invention is described below in greater detail.

The charge transporting composition of the invention is a charge transporting composition for forming a charge transporting thin film in a photovoltaic conversion device having a NFA active layer, and is characterized by including a charge transporting substance composed of a polythiophene derivative that includes repeating units of formula (1) below, a surfactant and a solvent, which electron-accepting dopant substance includes at least one compound selected from arylsulfonic acids of formula (2) below and heteropolyacids. In this invention, “solids” refers collectively to all of the ingredients in the charge transporting composition other than the solvent. Also, “NFA active layer” refers herein to an active layer in which the NFA content is more than 50 wt % of the n-type semiconductor included in the active layer.

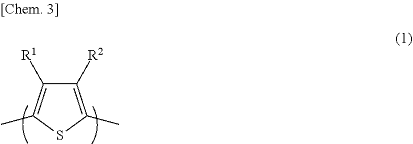

In the formula, R¹ and R² are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, an aryloxy group of 6 to 20 carbon atoms, —O[z—O]_{—R}^{e}, a sulfonic group or a sulfonate group, or R¹ and R² are bonded together to form —O—Y—O—, Y is an alkylene group of 1 to 40 carbon atoms which may include an ether bond and may be substituted with a sulfonic group or a sulfonate group; Z is an alkylene group of 1 to 40 carbon atoms which may be substituted with a halogen atom; p is an integer of 1 or more; and R^{e} is a hydrogen atom, an alkyl group of 1 to 40 carbon atoms which may be substituted with a sulfonic group or a sulfonate group, a fluoroalkyl group of 1 to 40 carbon atoms which may be substituted with a sulfonic group or a sulfonate group, or an aryl group of 6 to 20 carbon atoms which may be substituted with a sulfonic group or a sulfonate group.

The alkyl group of 1 to 40 carbon atoms may be linear, branched or cyclic. Specific examples include methyl, ethyl, n-propyl, isopropyl, n-butyl, isobutyl, s-butyl, t-butyl, n-pentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl, n-eicosanyl, behenyl, triacontyl and tetracontyl groups. In this invention, an alkyl group of 1 to 18 carbon atoms is preferred; an alkyl group of 1 to 8 carbon atoms is more preferred.

The fluoroalkyl group of 1 to 40 carbon atoms is not particularly limited so long as it is an alkyl group of 1 to 40 carbon atoms in which at least one hydrogen atom on a carbon atom is substituted with a fluorine atom. Specific examples include fluoromethyl, difluoromethyl, perfluoromethyl, 1-fluoroethyl, 2-fluoroethyl, 1,2-difluoroethyl, 1,1-difluoroethyl, 2,2-difluoroethyl, 1,1,2-trifluoroethyl, 1,2,2-trifluoroethyl, 2,2,2-trifluoroethyl, 1,1,2,2-tetrafluoroethyl, 1,2,2,2-tetrafluoroethyl, perfluoroethyl, is 1-fluoropropyl, 2-fluoropropyl, 3-fluoropropyl, 1,1-difluoropropyl, 1,2-difluoropropyl, 1,3-difluoropropyl, 2,2-difluoropropyl, 2,3-difluoropropyl, 3,3-difluoropropyl, 1,1,2-trifluoropropyl, 1,1,3-trifluoropropyl, 1,2,3-trifluoropropyl, ,3,3-trifluoropropyl, 2,2,3-trifluoropropyl, 2,3,3-trifluoropropyl, 3,3,3-trifluoropropyl, 1,1,2,2-tetrafluoropropyl, 1,1,2,3-tetrafluoropropyl, 1,2,2,,3-tetrafluoropropyl, 1,3,3,3-tetrafluoropropyl, 2,2,3,3-tetrafluoropropyl, 2,3,3,3-tetrafluoropropyl, 1,1,2,2,3-pentafluoropropyl, 1,2,2,3,3-pentafluoropropyl, 1,1,3,3,3-pentafluoropropyl, 1,2,3,3,3-pentafluoropropyl, 2,2,3,3,3-pentafluoropropyl, perfluoropropyl, perfluorobutyl, perfluoropentyl, perfluorohexyl, perfluoroheptyl and perfluorooctyl groups.

The alkoxy group of 1 to 40 carbon atoms may be one in which the alkyl group is linear, branched or cyclic. Specific examples include methoxy, ethoxy, n-propoxy, i-propoxy, c-propoxy, n-butoxy, i-butoxy, s-butoxy, t-butoxy, n-pentoxy, n-hexoxy, n-heptyloxy, n-octyloxy, n-nonyloxy, n-decyloxy, n-undecyloxy, n-dodecyloxy, n-tridecyloxy, n-tetradecyloxy, n-pentadecyloxy, n-hexadecyloxy, n-heptadecyloxy, n-octadecyloxy, n-nonadecyloxy and n-eicosanyloxy groups.

The fluoroalkoxy group of 1 to 40 carbon atoms is not particularly limited so long as it is an alkoxy group of 1 to 40 carbon atoms in which at least one hydrogen atom on a carbon atom is substituted with a fluorine atom. Specific examples include fluoromethoxy, difluoromethoxy, perfluoromethoxy, 1-fluoroethoxy, 2-fluoroethoxy, 1,2-difluoroethoxy, 1,1-difluoroethoxy, 2,2-difluoroethoxy, 1,1,2-trifluoroethoxy, 1,2,2-trifluoroethoxy, 2,2,2-trifluoroethoxy, 1,1,2,2-tetrafluoroethoxy, 1,2,2,2-tetrafluoroethoxy, perfluoroethoxy, 1-fluoropropoxy, 2-fluoropropoxy, 3-fluoropropoxy, 1,1-difluoropropoxy, 1,2-difluoropropoxy, 1,3-difluoropropoxy, 2,2-difluoropropoxy, 2,3-difluoropropoxy, 3,3-difluoropropoxy, 1,1,2-trifluoropropoxy, 1,1,3-trifluoropropoxy, 1,2,3-trifluoropropoxy, 1,3,3-trifluoropropoxy, 2,2,3-trifluoropropoxy, 2,3,3-trifluoropropoxy, 3,3,3-trifluoropropoxy, 1,1,2,2-tetrafluoropropoxy, 1,1,2,3-tetrafluoropropoxy, 1,2,2,3-tetrafluoropropoxy, 1,3,3,3-tetrafluoropropoxy, 2,2,3,3-tetrafluoropropoxy, 2,3,3,3-tetrafluoropropoxy, 1,1,2,2,3-pentafluoropropoxy, 1,2,2,3,3-pentafluoropropoxy, 1,1,3,3,3-pentafluoropropoxy, 1,2,3,3,3-pentafluoropropoxy, 2,2,3,3,3-pentafluoropropoxy and perfluoropropoxy groups.

The alkylene group of 1 to 40 carbon atoms may be linear, branched or cyclic. Specific examples include methylene, ethylene, propylene, trimethylene, tetramethylene, pentylene, hexylene, heptylene, octylene, nonylene, decylene, undecylene, dodecylene, tridecylene, tetradecylene, pentadecylene, hexadecylene, heptadecylene, octadecylene, nonadecylene and eicosanylene groups.

Specific examples of aryl groups of 6 to 20 carbon atoms include phenyl, tolyl, 1-naphthyl, 2-naphthyl, 1-anthryl, 2-anthryl, 9-anthryl, 1-phenanthryl, 2-phenanthryl, 3-phenanthryl, 4-phenanthryl and 9-phenanthryl groups. Phenyl, tolyl and naphthyl groups are preferred.

Specific examples of aryloxy groups of 6 to 20 carbon atoms include phenoxy, anthracenoxy, naphthoxy, phenanthrenoxy and fluorenoxy groups.

Examples of the halogen atoms include fluorine, chlorine, bromine and iodine atoms.

The sulfonic group and sulfonate group are exemplified by groups of formula (S) below.

[Chem. 4]

—SO₃M (S)

(wherein M is a hydrogen atom, an alkali metal selected from the group consisting of lithium, sodium and potassium, NH(R^{S})₃ or NHC₅H₅, each R^{S} being independently a hydrogen atom or an alkyl group of 1 to 6 carbon atoms which may have a substituent).

In cases where R^{S} is an alkyl group having a substituent, the substituent is exemplified by alkyl groups of 1 to 6 carbon atoms, alkoxy groups of 1 to 6 carbon atoms, aryl groups of 6 to 20 carbon atoms, a hydroxyl group, an amino group and a carboxyl group.

Examples of alkyl groups of 1 to 6 carbon atoms include the same groups as mentioned in connection with the above-described alkyl groups.

Specific examples of alkoxy groups of 1 to 6 carbon atoms include methoxy, ethoxy, n-propoxy, i-propoxy and n-butoxy groups. Specific examples of aryl groups of 6 to 20 carbon atoms include phenyl, tolyl, 1-naphthyl, 2-naphthyl, 1-anthryl, 2-anthryl, 9-anthryl, 1-phenanthryl, 2-phenanthryl, 3-phenanthryl, 4-phenanthryl and 9-phenanthryl groups.

A hydroxyl group is especially preferred as the substituent. Specific examples of alkyl groups having a hydroxyl group include 2-hydroxyethyl, 3-hydroxypropyl, 2-hydroxypropyl and 2,3-dihydroxypropyl groups.

Of these, R^{S} is preferably a hydrogen atom or a linear or branched alkyl group of 1 to 3 carbon atoms. A hydrogen atom and a methyl group are more preferred.

In above formula (1), it is preferable for R¹ and R² to each be independently a hydrogen atom, a fluoroalkyl group of 1 to 40 carbon atoms, an alkoxy group of 1 to 40 carbon atoms, —O[C(R^{a}R^{b})—C(R^{c}R^{d})—O]ₚ—R^{e}, —OR^{f}, a sulfonic group or a sulfonate group, or for R¹ and R² to bond together to form —O—Y—O—.

R^{a} to R^{d} are each independently a hydrogen atom, an alkyl group of 1 to 40 carbon atoms, a fluoroalkyl group of 1 to 40 carbon atoms, or an aryl group of 6 to 20 carbon atoms. Specific examples of these groups include the same as those mentioned above.

Of these, it is preferable for R^{a} to R^{d} to each be independently a hydrogen atom an alkyl group of 1 to 8 carbon atoms, a fluoroalkyl group of 1 to 8 carbon atoms or a phenyl group.

R^{e} represents a hydrogen atom, an alkyl group of 1 to 40 carbon atoms, a fluoroalkyl group of 1 to 40 carbon atoms or an aryl group of 6 to 20 carbon atoms. Specific examples of these groups include the same as those mentioned above.

Of these, R^{e} is preferably a hydrogen atom, an alkyl group of 1 to 8 carbon atoms, a fluoroalkyl group of 1 to 8 carbon atoms, or a phenyl group. A hydrogen atom, methyl group, propyl group or butyl group is more preferred,

Also, the subscript ‘p’ is preferably from 1 to 5, and is more preferably 1, 2 or 3.

R^{f} is a hydrogen atom, an alkyl group of 1 to 40 carbon atoms, a fluoroalkyl group of 1 to 40 carbon atoms or an aryl group of 6 to 20 carbon atoms. A hydrogen atom, an alkyl group of 1 to 8 carbon atoms, a fluoroalkyl group of 1 to 8 carbon atoms or a phenyl group is preferred; —CH₂CF₃ is more preferred.

In this invention, R¹ is preferably a hydrogen atom, a sulfonic group or a sulfonate group, and more preferably a sulfonic group or a sulfonate group, and R² is preferably an alkoxy group of 1 to 40 carbon atoms or —O—[Z—O]ₚ—R^{e}, more preferably —O[C(R^{a}R^{b})—C(R^{c}R^{d})—O]ₚ—R^{e} or —OR^{f}, and even more preferably —O[C(R^{a}R^{b})—C(R^{c}R^{d})—O]ₚ—R^{e}, —O—CH₂CH₂—O—CH₂CH₂—O—CH₃, —O—CH₂CH₂—O—CH₂CH₂—OH or —O—CH₂CH₂—OH; or R¹ and R² are mutually bonded to form —O—Y—O—.

For example, the polythiophene derivative according to a preferred embodiment of the invention includes repealing units in which R¹ is a sulfonic group or sulfonate group and R² is other than a sulfonic group or sulfonate group, or includes repeating units in which R¹ and R² are bonded together to form —O—Y—O—.

The polythiophene derivative preferably includes repeating units in which R¹ is a sulfonic group or sulfonate group and R² is an alkoxy group of 1 to 40 carbon atoms or —O[z—O]_{—R}^{e}, or includes repeating units in which R¹ and R² are bonded together to form —O—Y—O—.

The polythiophene derivative more preferably includes repeating units in which R¹ is a sulfonic group or a sulfonate group, and R² is —O[C(R^{a}R^{b})—C(R^{c}R^{d})—O]ₚ—R^{e} or —OR^{f}.

The polythiophene derivative even more preferably includes repeating units in which R¹ is a sulfonic group or a sulfonate group, and R² is —O[C(R^{a}R^{b})—C(R^{c}R^{d})—O]ₚ—R^{e}, or repeating units in which R¹ and R² are bonded together to form —O—Y—O—.

The polythiophene derivative still more preferably includes repeating units in which R¹ is a sulfonic group or a sulfonate group, and R² is —O—CH₂CH₂—O—CH₂CH₂—O—CH₃, —O—CH₂CH₂—O—CH₂CH₂—OH or —O—CH₂CH₂—OH, or includes repeating units in which R¹ and R² are bonded together to form groups of formula (Y1) and/or (Y2) below.

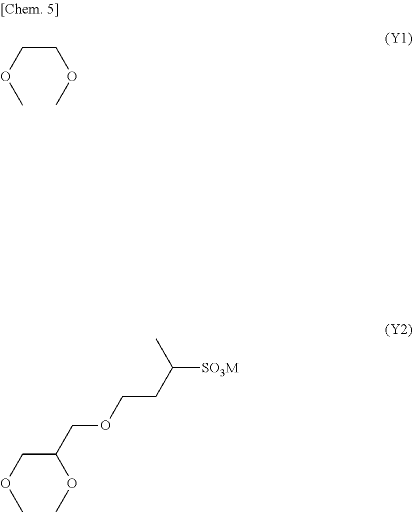

Specific preferred examples of the above polythiophene derivatives include polythiophenes having at least one type of repeating unit of formulas (1-1) to (1-5) below.

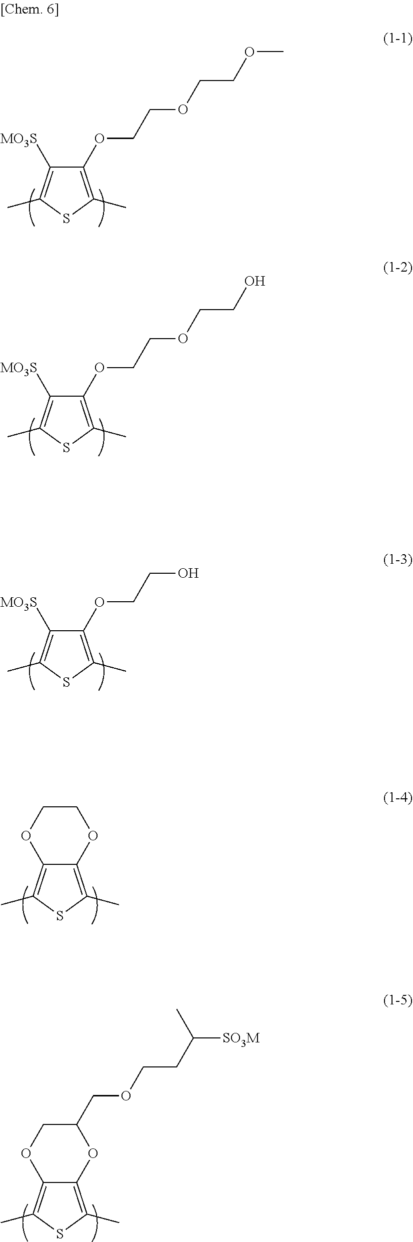

The preferred structure of the polythiophene derivative is exemplified by polythiophene derivatives having a structure of formula (1a) below. In the following formula, the respective units may be randomly bonded or may be bonded to form a block polymer.

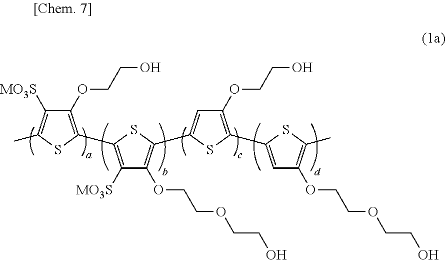

In the formula, the subscripts ‘a’ to ‘d’ represent molar ratios of the respective units and satisfy the conditions 0≤a≤1, 0≤b≤1, 0<a+b≤1, 0≤c<1, 0≤d<1 and a+b+c+d=1. M is the same as described above.

In addition, the above polythiophene derivative may be a homopolymer or a copolymer (including statistical, random, gradient and block copolymers). In terms of polymers containing a monomer A and a monomer B, examples of such block copolymers include A-B diblock copolymers, A-B-A triblock copolymers and (AB)ₘ- multiblock copolymers. The polythiophene may include repeating units derived from other types of monomers (such as thienothiophenes, selenophenes, pyrroles, furans, tellurophenes, anilines, arylamines and arylenes (e.g., phenylene, phenylene vinylene and fluorene).

In the present invention, the content of repeating units represented by formula (1) in the polythiophene derivative is preferably more than 50 mol %, more preferably at least 80 mol %, even more preferably at least 90 mol %, still more preferably at least 95 mol %, and most preferably 100 mo l%, of all the repeating units included in the polythiophene derivative.

The content of repeating units having a sulfonic group or sulfonate group is preferably at least 10 mol %, more preferably at least 30 mol %, even more preferably at least 50 mol %, and most preferably 100 mol %, of the repeating units represented by formula (1) in the polythiophene derivative.

In the present invention, depending on the purity of the starting monomer used in polymerization, the polymer that is formed may include repeating units derived from impurities. The above term ‘homopolymer’ refers to a polymer containing repeating units derived from one type of monomer, but may include repeating units derived from impurities.

The polythiophene derivative in this invention is preferably a polymer in which basically all of the repeating units are repeating units of formula (1), and is more preferably a polymer which includes at least one type of repeating unit of above formulas (1-1) to (1-5).

In cases where the polythiophene derivative includes repeating units having sulfonic groups, to further increase the solubility and dispersibility in an organic solvent, it is preferable to render the polythiophene derivative into an amine adduct in which an amine compound has been added to at least some of the sulfonic groups included in the polythiophene derivative.

Amine compounds that can be used to form an amine adduct are exemplified by primary amine compounds, including monoalkylamine compounds such as methylainine, ethylamine, n-propylamine, isopropylamine, n-butylamine, isobutylamine, s-butylatnine, t-butylamine, n-pentylamine, n-hexylamine, n-heptylamine, n-octylamine, 2-ethylhexylamine, n-nonylamine, n-decylamine, n-undecylamine, n-dodecylamine, n-tridecylamine, n-tetradecylamine, n-pentadecylamine, n-hexadecylamine, n-heptadecylamine, n-octadecylamine, n-nonadecylamine and n-eicosanylamine, and monoarylamine compounds such as aniline, tolylamine, 1-napthylamine, 2-naphthylamine, 1-arahtylamine, 2-anthrylamine, 9-anthrylamine, 1-phenanthrylamine, 2-phenanthrylamine, 3-phenanthrylamine, 4-phenanthrylamine and 9-phenanthrylamine, secondary amine compounds, including dialkylamine compounds such as N-ethylmethylamine, N-methyl-n-propylamine, N-methylisopropylamine, N-methyl-n-butarnine, N-methyl-s-butylamine, N-methyl-t-butylamine, N-methylisobutylamine, diethylamine, N-ethyl-n-propylamine, N-ethylisopropylamine, N-ethyl-n-butylamine, N-ethyl-s-butylamine, N-ethyl-t-butylamine, dipropylamine, N-n-propylisopropylamine, N-n-propyl-n-butylamine, N-n-propyl-s-butylamine, diisopropylamine, N-n-butylisopropylamine, N-t-butylisopropylamine, di(n-butyl)amine, di(s-butyl)amine, diisobutylamine, aziridine (ethyleneimine), 2-methylaziridine (propyleneimine), 2,2-dimethylaziridine, azetidine (trimethyleneimine), 2-methylazetidine, pyrrolidine, 2-methylpyrrolidine, 3-methylpyrrolidine, 2,5-dimethylpyrrolidine, piperidine, 2,6-dimethylpiperidine, 3,5-dimethylpiperidine, 2,2,6,6-tetramethylpiperidine, hexamethyleneimine, heptamethyleneimine and octamethyleneimine, diatylamine compounds such as diphenylamine, N-phenyl-1-naphthylamine, N-phenyl-2-naphthylamine, 1,1′-dinaphthylamine, 2,2′-dinaphthylamine, 1,2′-dinaphthylamine, carbazole, 7H-benzo[c]carbazole, 11H-benzo[a]carbazole, 7H-dibenzo[c,g]carbazole and 13H-dibenzo[a,i]carbazole, and alkylarylamine compounds such as N-methylaniline, N-ethylaniline, N-n-propylaniline, N-isopropylaniline, N-isobutylaniline, N-methyl-1-naphthylamine, N-ethyl-1-naphthylamine, N-n-propyl-1-naphthylamine, indoline, isoindoline, 1,2,3,4-tetrahydroquinoline and 1,2,3,4-tetrahydroisoquinoline; and tertiary amine compounds, including trialkylamine compounds such as N,N-dimethylethylamine, N,N-dimethyl-n-propylamine, N,N-dimethylisopropylamine, N,N-dimethyl-n-butylamine, N,N-dimethyl-s-butylamine, N,N-dimethyl-t-butylamine, N,N-dimethylisobutylamine, N,N-diethylmethylamine, N-methyldi(n-propyl)amine, N-methyldiisopropylamine, N-methyldi(n-butyl)amine, N-methyldiisobutylamine, triethylamine, N,N-diethyl-n-butylamine, N,N-diisopropylethylamine, N,N-di(n-butyl)ethylamine, tri(n-propyl)amine, tri(i-propyl)amine, tri(n-butyl)amine, tri(i-butyl)amine, 1-methylazetidine, 1-methylpyrrolidine and 1-methylpiperidine, triarylamine compounds such as triphenylamine, alkyldiarylamine compounds such as N-methyldiphenylamine, N-ethyldiphenylatnine, 9-methylcarbazole and 9-ethylcarbazole, and dialkylarylamine compounds such as N,N-diethylaniline, N,N-di(p-propyl)aniline, N,N-di(i-propyl)aniline and N,N-di(n-butyl)aniline. Taking into account the balance between the solubility of the amine adduct and the charge transporting properties of the resulting charge transporting thin film, a tertiary amine compound is preferred, a trialkylamine compound is more preferred, and triethylamine is even more preferred.

The amine adduct can be obtained by charging the polythiophene derivative into the amine itself or a solution thereof, and thoroughly stirring.

The polythiophene derivative or amine adduct thereof used in this invention may be one that has been treated with a reducing agent.

In some of the repeating units making up the polythiophene derivative or the amine adduct thereof, the chemical structure is sometimes an oxidized structure called a “quinoid structure.” The term ‘quinoid structure’ is used in contrast with the term ‘benzenoid structure’; the latter term refers to a structure that includes an aromatic ring, whereas the former term refers to the structure that forms when a double bond within the aromatic ring moves outside of the ring (as a result of which the aromatic ring disappears) and two exocyclic double bonds conjugate with the other double bond remaining within the ring. To one skilled in the art, the relationship between both structures will be readily apparent from the relationship between the structures of benzoquinone and hydroquinone. Quinoid structures for repeating units on various conjugated polymers are familiar to those skilled in the art. As one example, formula (1′) below shows the quinoid structure for the repeating units of a polythiophene derivative containing repeating units of formula (1) above.

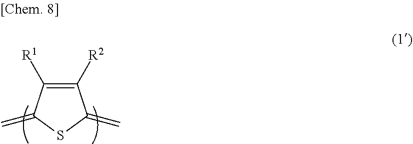

In formula (1′), R¹ and R² are as defined in above formula (1).

This quinoid structure arises as a result of a “doping” reaction, which is a process in which the polythiophene derivative containing repeating units of formula (1) incurs oxidizing reactions due to the dopant, forming some of the structures called “polaron structures” and “bipolaron structures” that impart electron transporting properties to the polythiophene derivative. These structures are commonly known. In the production of an organic solar cell, it is essential to introduce “polaron structures” and/or “bipolaron structures.” In fact, during the fabrication of organic solar cells, when the thin film that has been formed from a charge transporting composition is baked, this is achieved by intentionally inducing the above doping reaction. The reason why quinoid structures are present in the polythiophene derivative before inducing this doping reaction is thought to be that the polythiophene derivative has precipitated an unintended oxidation reaction similar to a doping reaction at this stage of production (especially the sulfonation step therein).

There is a correlation between the amount of quinoid structures included in the polythiophene derivative and the solubility or dispersibility of the polythiophene derivative in organic solvents. When the amount of quinoid structures increases, the solubility and dispersibility tend to decrease. Hence, introducing quinoid structures after a thin film has formed from the charge transporting composition does not pose a problem, but when too many quinoid structures are introduced onto the polythiophene derivative by the above unintended oxidation reactions, this may hinder production of the charge-transporting composition. There is known to be some variability in the solubility or dispersibility of polythiophene derivatives in organic solvents. One reason appears to be that the amount of quinoid structures introduced onto the polythiophene by the above unintended oxidation reactions fluctuates according to differences in the various polythiophene derivative production conditions.

Hence, when the polythiophene derivative is subjected to reduction treatment using a reducing agent, even should too many quinoid structures be introduced onto the polythiophene derivative, the number of quinoid structures decreases due to reduction and the solubility or dispersibility of the polythiophene derivative in organic solvents rises, thus making it possible to stably produce a good charge transporting composition which gives a thin film of excellent uniformity.

The reduction treatment conditions are not particularly limited, so long as the above quinoid structure can be reduced and suitably converted to a non-oxidized structure, i.e., a benzenoid structure (for example, in the polythiophene derivative containing repeating units of formula (1), so long as the quinoid structure represented by formula (1′) can be converted to the structure represented by formula (1)). For example, this treatment can be carried out by simply bringing the polythiophene derivative or amine adduct into contact with a reducing agent, either in the presence or absence of a suitable solvent.

Such a reducing agent is not particularly limited, provided that reduction is suitably effected. For example, ammonia water, hydrazine and the like which are readily available as commercial products are suitable.

The amount of reducing agent differs according to the type of reducing agent used and so cannot be strictly specified. However, in order to have reduction suitably take place, the amount of reducing agent per 100 parts by weight of the polythiophene derivative or amine adduct to be treated is generally at least 0.1 part by weight. In order to not have excess reducing agent remain behind, the amount is generally not more than parts by weight.

An example of a specific reduction treatment method is to stir the polythiophene derivative or amine adduct overnight at room temperature in 28% ammonia water. The solubility or dispersihility of the polythiophene derivative or amine adduct in organic solvent will sufficiently increase with reduction treatment under such relatively mild conditions.

When an amine adduct of a polythiophene derivative is used in the charge transporting composition of the invention, the above reduction treatment may be carried out before forming the amine adduct or may be carried out after forming the amine adduct.

As a result of the change in solubility or dispersibility of the polythiophene derivative or amine adduct thereof in solvents due to such reduction treatment, polythiophene derivative or amine adduct thereof which was not dissolved in the reaction system at the start of treatment is sometimes dissolved at the completion of treatment. In such cases, the polythiophene derivative or amine adduct thereof can be recovered by, for example, adding an organic solvent that is incompatible with the polythiophene derivative or amine adduct thereof (such as acetone or isopropyl alcohol in the case of a sulfonated polythiophene) to the reaction system to induce precipitation of the poly thiophene derivative or amine adduct thereof, and then carrying out filtration.

The weight-average molecular weight of the polythiophene derivative containing repeating units of formula (1) or an amine adduct thereof is preferably from about 1,000 to about 1,000,000, more preferably from about 5,000 to about 100,000, and even more preferably from about 10,000 to about 50,000. By setting the weight-average molecular weight at or above the lower limit, a good electrical conductivity can be reproducibly obtained; by setting the weight-average molecular weight at or below the upper limit, the solubility in solvents rises. The weight-average molecular weight is a polystyrene equivalent value obtained by gel permeation chromatography.

The polythiophene derivative or amine adduct thereof included in the charge transporting composition of the invention may be a single polythiophene derivative containing repeating units of formula (1) or an amine adduct thereof or may be two or more such polythiophene derivatives or amine adducts thereof.

Also, the polythiophene derivative containing repeating units of formula (1) that is used may be a commercial product or may be a polythiophene derivative polymerized by a known method from a thiophene derivative or the like as the starting material. In either case, it is preferable to use a product that has been purified by a method such as re-precipitation or ion exchange. By using a purified product, the properties of organic solar cells having a thin film obtained from the charge transporting composition of the invention can be further increased. An example of a commercial product is SELFTRON® from Tosoh Corporation.

The sulfonation of conjugated polymers and sulfonated conjugated polymers (including sulfonated polythiophenes) are described in U.S. Pat. No. 8,017,241 to Seshadri et al. Also, sulfonated polythiophenes are described in WO 2008/073149 A1 and 2016/171935 A1.

In the present invention, at least some of the polythiophene derivative containing repeating units of formula (1) or an amine adduct thereof included in the charge transporting composition is dissolved in an organic solvent.

A polythiophene derivative containing repeating units of formula (1) or an amine adduct thereof and a charge transporting substance composed of another charge transporting compound may be used together as the charge transporting substance in this invention, although it is preferable for only a polythiophene derivative containing repeating units of formula (1) or an amine adduct thereof to be included.

In an organic thin-film solar cell, the ionization potential of the hole collecting layer is preferably a value close to the ionization potential of the p-type semiconductor material in the active layer. The absolute value of this difference is preferably from 0 to 1 eV, more preferably from 0 to 0.5 eV, and even more preferably from 0 to 0.2 eV.

The charge transporting composition of the invention thus includes, for the purpose of adjusting the ionization potential of the charge transporting thin film obtained using the composition, at least one type of electron-accepting dopant substance selected from the group consisting of arylsulfonic acid compounds of formula (2) below and heteropolyacids.

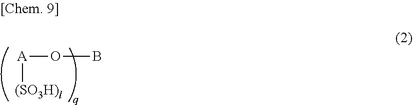

In the formula, A is a naphthalene ring or an anthracene ring, B is a perfluorobiphenyl group having a valence of from 2 to 4, the letter is an integer which represents the number of sulfonic groups bonded to A and satisfies the condition 1≤l≤4, and q is an integer from 2 to 4 which represents the number of bonds between B and X) and heteropolyacids.

An example of an arylsulfonic acid compound that can be suitably used in this invention is the compound of formula (2-1) below.

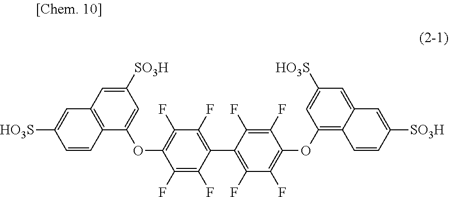 [SMILES: O=S(=O)(O)c1ccc2c(Oc3c(F)c(F)c(-c4c(F)c(F)c(Oc5cc(S(=O)(=O)O)cc6cc(S(=O)(=O)O)ccc56)c(F)c4F)c(F)c3F)cc(S(=O)(=O)O)cc2c1]

The arylsulfonic acid compound of formula (2) can be synthesized by a known method. For example, it can be synthesized by the method described in WO 2006/025342 A1.

Examples of heteropolyacids include inorganic oxidizing agents such as heteropolyacid compounds (e.g., the phosphomolybdic acid, phosphotungstic acid, phosphotungstomolybdic acid, silicotungstic acid, sodium phosphomolybdate and phosphovanadomolybdic acid mentioned in WO 2010/058777 A1). In this invention, phosphomolybdic acid and phosphotungstic acid are preferred.

The content of the electron-accepting dopant substance is suitably set while taking into account the charge transporting properties to be manifested and the type of charge transporting substance. The electron-accepting dopant substance content is generally from 0.05 to 10 parts by weight, preferably from 0.1 to 3.0 parts by weight, and more preferably from 0.2 to 2.0 parts by weight, per part by weight of the charge transporting substance.

The combined use of an arylsulfonic acid compound of formula (2) and a heteropolyacid is preferred. In such a case, the mixing ratio by weight of the arylsulfonic acid compound of formula (2) and the heteropolyacid is preferably from 10:90 to 90:10, and more preferably from 20:80 to 80:20.

The charge transporting composition of the invention may include electron-accepting dopant substances other than the above arylsulfonic acid compound of formula (2) and the above heteropolyacid. Specific examples of such other electron-accepting dopant substances include strong inorganic acids such as hydrogen chloride, sulfuric acid, nitric acid and phosphoric acid; Lewis acids such as aluminum(III) chloride (AlCl₃), titanium(IV) tetrachloride (TiCl₄), boron tribromide (BBr₃), a boron trifluoride-ether complex (BF₃·OEt₂), iron(III) chloride (FeCl₃), copper(II) chloride (CuCl₂), antimony(V) pentachloride (SbCl₅), arsenic(V) pentafluoride (AsF₅), phosphorus pentafluoride (PF₅) and tris(4-bromophenypaluminum hexachloroantimonate (TBPAH); strong organic acids, including arylsulfonic acid compounds such as benzenesulfonic acid, tosylic acid, hydroxybenzenesulfonic acid, 5-sulfosalicylic acid, dodecylbenzenesulfonic acid, polystyrenesulfonic acid, the 1,4-benzodioxanedisulfonic acid compounds mentioned in WO 2005/000832 A1, the naphthalenesulfonic acid compounds mentioned in WO 2006/025342 A1 (excluding those encompassed by arylsulfonic acid compounds of formula (2)), the dinonylnaphthalenesulfonic acid mentioned in JP-A 2005-108828 A1 and 1,3,6-naphthalenetrisulfonic acid, and camphorsulfonic acid; and organic oxidizing agents such as 7,7,8,8-tetracyanoquinodimethane (TCNQ), 2,3-dichloro-5,6-dicyano-1,4-benzoquinone (DDQ), and iodine. These may be used singly or two or more may be used in combination.

When another electron-accepting dopant substance is included, the content thereof is preferably not more than 20 wt %, and more preferably not more than 10 wt %, of the overall electron-accepting dopant substance. Not including another electron-accepting dopant substance is even more preferable.

The charge transporting composition of the invention may include, from the standpoint of film formability, a surfactant. The surfactant is not particularly limited. For example, use can be made of a fluorosurfactant or a silicone-based surfactant. In this invention, the use of a fluorosurfactant is preferred.

The fluorosurfactant used in the invention may be acquired as a commercial product.

Examples of such commercial products include, but are not limited to, Capstone® FS-10, FS-22, FS-30, FS-31, FS-34, FS-35, FS-50, FS-51, FS-60, FS-61, FS-63, FS-64, FS-65, FS-66, FS-81, FS-83 and FS-3100 from DuPont de Nemours, Inc.; Noigen FN-1287 from DKS Co., Ltd.; and Megaface F-444, F-477 and F-559 from DIC Corporation.

The nonionic surfactants Capstone FS-30, 31, 34, 35 and 3100, Noigen FN-1287 and Megaface F-559 are especially preferred.

The fluorosurfactant is not particularly limited so long as it includes fluorine atoms, and may be cationic, anionic or nonionic, although a fluorinated nonionic surfactant is to preferred. At least one fluorinated nonionic surfactant selected from those of formulas (A1) and (B1) below is especially preferred.

[Chem. II]

RCOO(CH₂CH₂O)ₙH (A1)

R(CH₂CH₂O)ₙH (B1)

In these formulas, R is a fluorine atom-containing monovalent organic group, and n is an integer from 1 to 20.

Specific examples of the organic group include alkyl groups of 1 to 40 carbon atoms, aryl groups of 6 to 20 carbon atoms, aralkyl groups of 7 to 20 carbon atoms and heteroaryl groups of 2 to 20 carbon atoms.

Specific examples of the aralkyl groups of 7 to 20 carbon atoms include benzyl, p-methylphenylmethyl, m-methylphenylmethyl, o-ethylphenylmethyl, n-ethylphenylmethyl, p-ethylphenylmethyl, 2-propylphenylmethyl, 4-isopropylphenylmethyl, 4-isobutylphenylinethyl and α-naphthylmethyl groups.

Specific examples of the heteroaryl groups include 2-thienyl, 3-thienyl, 2-furanyl, 3-furanyl, 2-oxazolyl, 4-oxazolyl, 5-oxazolyl, 3-isooxazolyl, 4-isooxazolyl, 5-isooxazolyl, 2-thiazolyl, 4-thiazolyl, 3-isothiazolyl, 4-isothiazolyl, 5-isothiazolyl, 2-imidazolyl, 2-pyridyl, 3-pyridyl, 4-pyridyl, 2-pyrazyl, 3-pyrazyl, 5-pyrazyl, 6-pyrazyl, 2-pyrimidyl, 4-pyrimidyl, 5-pyrimidyl, 6-pyrimidyl, 3-pyridazyl, 4-pyridazyl, 5-pyridazyl, 6-pyridazyl, 1,2,3-triazin-4-yl, 1,2,4-triazin-6-yl and 1,3,5-triazin-2-yl groups.

Specific examples of the alkyl groups and aryl groups include the same as those mentioned above.

The subscript ‘n’ is not particularly limited, so long as it is an integer from 1 to 20, although an integer from I to 10 is preferred.

Of these, at least one fluorinated nonionic surfactant selected from perfluoroalkyl polyoxyethylene esters of formula (A2) below and perfluoroalkyl polyoxyethylene ethers of formula (B2) below having a perfluoroalkyl group R_{f} of 1 to 40 carbon atoms, and fluorotelomer alcohols, is more preferred.

[Chem. 12]

R_{f}COO(CH₂CH₂O)ₙH (A2)

R_{f}(CH₂CH₂O)ₙH (B2)

In these formulas, n has the same meaning as above.

Specific examples of perfluoroalkyl groups of 1 to 40 carbon atoms include alkyl groups of 1 to 40 carbon atoms in which all the hydrogen atoms are substituted with fluorine atoms.

When a surfactant is included, the content thereof is not particularly limited. However, taking into consideration the balance between an increase in the film-forming properties on an active layer and a decrease in the photoelectric conversion efficiency of the resulting device, the content is preferably from about 0.01 to about 0.1 wt %, more preferably from 0.02 to 0.08 wt %, and most preferably from 0.03 to 0.06 wt %, of the overall composition.

In addition, the composition of the invention may include one or more type of metal oxide nanoparticles. The term ‘nanoparticles’ refers to fine particles for which the primary particles have a nanometer-order (typically 500 nm or less) average particle size. Metal oxide nanoparticles refer to a metal oxide formed as nanoparticles.

The term ‘nanoparticles’ refers to fine particles for which the primary particles have a nanometer-order (typically 500 nm or less) average particle size. Metal oxide nanoparticles refer to a metal oxide formed as nanoparticles.

The primary particle size of the metal oxide nanoparticles used in the invention is to not particularly limited so long as it is a nanometer-order size. However, to further increase adhesion to the active layer, the primary particle size is preferably from 2 to 150 nm, more preferably from 3 to 100 nm, and even more preferably from 5 to 50 nm. The particle size is a measured value obtained using a nitrogen adsorption isotherm according to the BET method.

In addition to metals in the normal sense of the word, the metal making up the metal oxide nanoparticles in the invention also encompasses semi-metals.

The metals in the normal sense are not particularly limited, although the use of one, two or more selected from the group consisting of tin (Sn), titanium (Ti), aluminum (Al), zirconium (Zr), zinc (Zn), niobium (Nb), tantalum (Ta) and tungsten (W) is preferred.

Semi-metals refer to elements whose chemical and/or physical properties are midway between those of metals and nonmetals, Although a universal definition of non-metals does not exist, in this invention, a total of six elements are considered to be semi-metals: boron (B), silicon (Si), germanium (Ge), arsenic (As), antimony (Sb) and tellurium (Te). These semi-metals may be used singly or two or more may be used in combination. They may also be used in combination with metals in the normal sense.

The metal oxide nanoparticles used in this invention preferably include oxides of one, two or more metals selected from among boron (B), silicon (Si), germanium (Ge), arsenic (As), antimony (Sb), tellurium (Te), tin (Sn), titanium (Ti), aluminum (Al), zirconium (Zr), zinc (Zn), niobium (Nb), tantalum (Ta) and tungsten (W). In cases where two or more metals are combined, the metal oxide may be a mixture of the oxides of each individual metal or may be a mixed oxide containing a plurality of metals.

Specific examples of metal oxides include B₂O₃, B₂O, SiO₂, SiO, GeO₂, GeO, As₂O₄, As₂O₃, As₂O₅, Sb₂O₃, Sb₂O₅, TeO₂, SnO₂, ZrO₂, Al₂O₃ and ZnO. B₂O₃, B₂O, SiO₂, SiO, GeO₂, GeO, As₂O₄, As₂O₃, As₂O₅, SnO₂, SnO, Sb₂O₃, TeO₂ and mixtures thereof are preferred. SiO₂ is more preferred.

The above metal oxide nanoparticles may include one or more type of organic capping group. This organic capping group may be reactive or non-reactive. Examples of reactive organic capping groups include organic capping groups that are crosslinkable in to the presence of UV radiation or a radical initiator.

In particular, it is preferable in this invention to use as the metal oxide nanoparticles a silica sol of SiO₂ nanoparticles dispersed in a dispersing medium.

The silica sol used is not particularly limited, and may be suitably selected from is among known silica sols.

Commercial silica sols are generally in the form of liquid dispersions. Examples of commercial silica sols include those obtained by dispersing SiO₂ nanoparticles in various solvents, such as water, methanol, methyl ethyl ketone, methyl isobutyl ketone, N,N-dimethyl acetamide, ethylene glycol, isopropanol, methanol, ethylene glycol monopropyl ether, cyclohexarione, ethyl acetate, toluene and propylene glycol monornethyl ether acetate.

In particular, a silica sol in which the dispersant is an alcohol solvent or water is preferred in this invention; a silica sol in which the dispersant is an alcohol solvent is more preferred. The alcohol solvent is preferably a water-soluble alcohol; methanol, 2-propanol and ethylene glycol are more preferred.

Specific examples of commercial silica sols include, but are not limited to, water-dispersed silica sols such as Snowtex® ST-O, ST-OS, ST-O-40 and ST-OL from Nissan Chemical Corporation, and Silicadol 20, 30 and 40 from Nissan Chemical Industries, Ltd.; and organosilica sols such as Methanol Silica Sol, MA-ST-M, MA-ST-L, IPA-ST, IPA-ST-L, IPA-ST-ZL and EG-ST from Nissan Chemical Corporation.

The solids concentration of the silica sol, although not particularly limited, is preferably from 5 to 60 wt %, more preferably from 10 to 50 wt %, and even more preferably from 15 to 30 wt %.

When metal oxide nanoparticles are used, the content thereof is not particularly limited. However, to fully exhibit adhesion to the active layer, the content per 100 parts by weight of the charge transporting substance is preferably from 50 to 95 wt %, more preferably from 60 to 95 wt %, and even more preferably from 80 to 95 wt %.

In cases where the charge transporting substance is used as a solution or dispersion, the amount of metal oxide nanoparticles added is set based on the solids content of the charge transporting substance.

The inventive composition may also include an alkoxysilane. By including an alkoxysilane, it is possible to increase the solvent resistance and water resistance of the resulting thin film, to increase the electron blocking properties, and to set the HOMO level and LUMO level to optimal values for the active layer. The alkoxysilane may be a siloxane material.

Any one or more alkoxysilane from among tetraalkoxysilanes, trialkoxysilanes and dialkoxysilanes may be used as the alkoxysilane. Tetraethoxysilane, tetramethoxysilane, phenyltriethoxysilane, phenyltrimethoxysilane, methyltriethoxysilane, methyltrimethoxysilane, 3,3,3-trifluoropropyltrimethoxysilane, dimethyldiethoxysilane and dimethyldimethoxysilane are especially preferred; tetraethoxysilane is even more preferred.

Examples of siloxane materials include polysiloxanes such as poly(tetraethoxysilane) and poly(phenylethoxysilane) which can be obtained by reactions such as hydrolysis on the above alkoxysilane.

When an alkoxysilane is used, the content thereof is not particularly limited so long as it is an amount which elicits the above advantageous effects, although the weight ratio with respect to the polythiophene derivative used in the invention is preferably from 0.0001 to 100, more preferably from 0.01 to 50, and even more preferably from 0.05 to 10.

Where necessary, the charge transporting composition of the invention may further include a matrix polymer.

Specific examples of such matrix polymers include matrix polymers containing repeating units of formula (I) below and repeating units of formula (II) below.

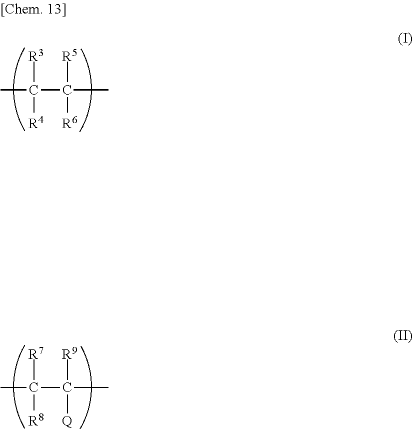

In these formulas. R³ , R⁴, R⁵ , R⁶ , R⁷ , R⁸ and R⁹ are each independently a hydrogen atom, a halogen atom, a fluoroalkyl group of 1 to 20 carbon atoms, or a perfluoroalkyl group of 1 to 20 carbon atoms; Q is —[OC(R^{h}Rⁱ)—C[R^{j}R^{k})]_{y}—O—[CR^{l}R^{m}]_{z}—SO₃H; R^{h}, Rⁱ, R^{j}, R^{k}, R^{l} and R^{m} are each independently a hydrogen atom, a halogen atom, a fluoroalkyl group of 1 to 20 carbon atoms, or a perfluoroalkyl group of 1 to 20 carbon atoms; y is from 0 to 10; and z is from 1 to 5.

The halogen atom, the fluoroalkyl group of 1 to 20 carbon atoms and the perfluoroalkyl group of 1 to 20 carbon atoms are exemplified in the same way as above.

It is preferable for R³, R⁴, R⁵ and R⁶ to be fluorine atoms or chlorine atoms; more preferable for R³, R⁵ and R⁶ to be fluorine atoms and R⁴ to be a chlorine atom; and even more preferable for R³, R⁴, R⁵ and R⁶ to all be fluorine atoms.

R⁷, R⁸ and R⁹ are preferably all fluorine atoms.

R^{h}, Rⁱ, R^{j}, R^{k}, R^{l} and RR^{m} are preferably fluorine atoms, fluoroalkyl groups of 1 to 8 carbon atoms or perfluoroalkyl groups of 1 to 8 carbon atoms.

R^{l} and R^{m} are more preferably fluorine atoms. Also, y is preferably 0 and z is preferably 2.

Also, it is preferable for R³, R⁵ and R⁶ to be fluorine atoms, for R⁴ to be a chlorine atom, for each of R^{l} and R^{m} to be a fluorine atom, for y to be 0, and for z to be 2.

Moreover, in some embodiments, it is preferable for each of R³, R⁴, R⁵ and R⁶ to be fluorine atoms, for each of R^{l} and R^{m} to be fluorine atoms, for y to be 0, and for z to be 2.

The ratio s:t between the number s of repeating units of formula (I) and the number t of repeating units of formula (II) is not particularly limited. The ratio s:t is preferably from 9:1 to 1:9, and more preferably from 8:2 to 2:8.

Matrix polymers that can be suitably used in this invention include those synthesized by known methods and commercial products. For example, a polymer containing repeating units of formula (I) and repeating units of formula (II) can be produced by carrying out copolymerization on a monomer of formula (Ia) below and a monomer of formula (IIa) below by a known polymerization process, and subsequently hydrolyzing the sulfonylfluoride groups, thereby converting them to sulfonic groups.

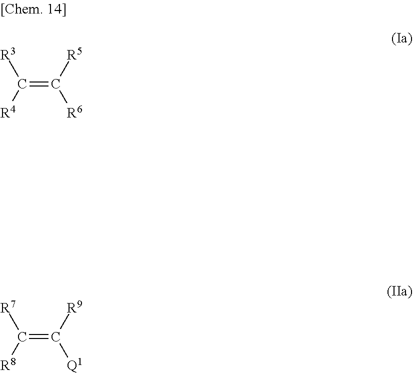

In the formulas, Q¹ is —[OC(R^{h}Rⁱ)—(R^{j}R^{k})]_{y}—O—[CR^{l}R^{m}]_{z}—SO₂F, and R³, R⁴, R⁵, R⁶, R⁷, R⁸, R⁹, R^{h}, Rⁱ, R^{j}, R⁵, R^{l}, R^{m}, y and z are as defined above.

For example, tetrafluoroethylene (TFE) and chlorotrifluoroethylene (CTFE) can be copolymerized with one or more fluorinated monomer containing a precursor group for sulfonic acid (examples of which include F₂C═CF—O—CF₂—CF₂—SO₂F, F₂C═CF—[O—CF₂—CR¹²F—O]_{y}—CF₂—CF₂—SO₂F (where R¹² is F or CF₃, and y is from 1 to 10), F₂C═CF—O—CF₂—CF₂—CF₂—SO₂F and F₂C═CF—OCF₂—CF₂—CF₂—CF₂—SO₂F).

In this invention, the “equivalent weight” of the matrix polymer refers to the weight of the matrix polymer per mole of acid groups present on the matrix polymer (g/mol). The equivalent weight of the matrix polymer is preferably from about 400 to about 15,000 g/mol, more preferably from about 500 to about 10,000 g/mol, even more preferably from about 500 to about 8,000 g/mol, still more preferably from about 500 to about 2,000 g/mol, and most preferably from about 600 to about 1,700 g/mol.

Such a matrix polymer may be acquired as a commercial product.

Examples of commercial products include NAFIONCR) from DuPont de Nemours, Inc., AQUIVION® from Solvay Specialty Polymers, and FLEMION® from AGC Inc.

In this invention, the matrix polymer is preferably a polyethersulfone containing one or more repeating unit having at least one sulfonic residue (—SO₃H).

The inventive composition may include other additives, provided that the objects of the invention can be achieved.

The types of additives used may be suitably selected from among known additives in accordance with the desired effects.

A high solubility solvent which is capable of dissolving well the polythiophene derivative and the electron-accepting dopant substance may be used as the solvent for preparing the charge transporting composition. A single high-solubility solvent may be used alone or two or more may be used in admixture. The amount of use may be set to from 5 to 100 wt % of all the solvent used in the composition.

Examples of such high-solubility solvents include water and organic solvents, including alcoholic solvents such as ethanol, 2-propanol, 1-butanol, 2-butanol, s-butanol, t-butanol and 1-methoxy-2-propanol, and amide-type solvents such as N-methylfonnamide, N,N-dimethylformamide, N,N-diethylfonnamide, N-methylacetamide, N,N-dimethyl acetamide, N-methylpyrrolidone and 1,3-dimethyl-2-imidazolidinone.

Of these, at least one selected from water and alcoholic solvents is preferred; water, ethanol and 2-propanol are more preferred.

The charge transporting substance and the electron accepting dopant substance are preferably in a state that is either completely dissolved or uniformly dispersed in the above solvent. From the standpoint of reproducibly obtaining a hole collecting layer that gives an organic thin-film solar cell having a high conversion efficiency, it is more preferable for these substances to be completely dissolved in the above solvent.

To increase the film formability and the dischargeability from a coating apparatus, the charge transporting composition of the invention may include at least one high-viscosity organic solvent having a viscosity at 25° C. of from 10 to 200 mPa·s, especially from 35 to 150 mPa·s, and a boiling point at normal pressure of from 50 to 300° C., especially from 150 to 250° C.

Examples of the high-viscosity organic solvent include, without particular limitation, cyclohexanol, ethylene glycol, 1,3-octylene glycol, diethylene glycol, dipropylene glycol, triethylene glycol, tripropylene glycol, 1,3-butanediol, 2,3-butanediol, 1,4-butanediol, propylene glycol and hexylene glycol.

When a high-viscosity organic solvent is used, it is preferable for the proportion in which it is added to be within a range where solids do not settle out; to the extent that solids do not settle out, the proportion is preferably from 1 to 80 wt % of all the solvent used in the composition.

In addition, another solvent capable of imparting film planarity at the time of heat treatment may be included for such purposes as to increase the ability of the composition to wet the coating surface, adjust the surface tension of the solvent, adjust the polarity and adjust the boiling point.

Examples of such solvents include butyl cellosolve, diethylene glycol diethyl ether, diethylene glycol dimethyl ether, diethylene glycol monoethyl ether acetate, diethylene glycol trionobutyl ether acetate, dipropylene glycol monomethyl ether, propylene glycol monomethyl ether, propylene glycol monomethyl ether acetate, ethyl carbitol, diacetone alcohol, γ-butyrolactone, ethyl lactate and n-hexyl acetate.

When another solvent is used, the proportion in which it is added is preferably from 1 to 90 wt %, and more preferably from 1 to 50 wt %, of all the solvent used in the composition.

Although the solids concentration of the inventive composition is suitably set while taking into account, for example, the viscosityand surface tension of the composition and the thickness of the thin film to be produced, the solids concentration is generally from about 0.1 to about 10.0 wt %, preferably from 0.5 to 5.0 wt %, and more preferably from about 1.0 to 3.0 wt %.

The viscosity of the charge transporting composition used in this invention is suitably adjusted according to the coating method while taking into account the thickness of the thin film to be produced and the solids concentration, but is generally from about 0.1 mPa·s to about 50 mPa·s at 25° C.

When preparing the charge transporting composition of the invention, so long as the solids uniformly dissolve or disperse in the solvent, the charge transporting substance, surfactant, metal oxide nanoparticles, electron-accepting dopant substance, solvent and the like can be mixed together in any order. That is, so long as the solids are uniformly dissolved or dispersed in the solvent, use can be made of any of the following methods: the method of dissolving the polythiophene derivative in the solvent, and subsequently dissolving the electron-accepting dopant substance in the resulting solution; the method of dissolving the electron-accepting dopant in the solvent and subsequently dissolving the polythiophene derivative in the resulting solution; and the method of mixing together the polythiophene derivative and the electron-accepting dopant substance, and subsequently pouring and dissolving the mixture in a solvent.

The matrix polymer and alkoxysilane may also be added in any order.

Preparation of the composition is generally carried out in an inert gas atmosphere at normal temperature and pressure, although it may be carried out in an open-air atmosphere (in the presence of oxygen) or under heating, provided that the compounds within the composition do not decompose and the composition does not undergo any large change in makeup.

The hole collecting layer of the invention can be formed by coating the above-described composition onto the anode in the case of a normal stack-type organic thin-film solar cell, or onto the active layer in the case of an inverted stack-type organic thin-film solar cell, and then baking the composition

In coating, the optimal technique from among various types of wet processes such as drop casting, spin coating, blade coating, dip coating, roll coating, bar coating, die coating, inkjet coating and printing methods (e.g., relief printing, intaglio printing, lithography, screen printing) may be used while taking into account, for example, the viscosity and surface tension of the composition and the desired thickness of the thin film.

Coating is generally carried out in an inert gas atmosphere at normal temperature and pressure, although it may be carried out in an open-air atmosphere (in the presence of oxygen) or may be carried out under heating, provided that the compounds within the composition do not decompose and the composition does not undergo any large change in makeup.

The film thickness, although not particularly limited, is in all cases preferably from about 0.1 mm to about 800 nm, and more preferably from about 30 mm to about 500 nm. Methods for changing the film thickness include methods that involve changing the solids concentration within the composition and methods that involve changing the amount of solution applied during coating.

Methods for producing organic thin-film solar cells using the charge transporting composition of the invention as a hole collecting layer-forming composition are described below, although the invention is not limited thereby.

### (1) Normal Stack-Type Organic Thin-Film Solar Cell

### Formation of Anode Layer

### Step of Producing Transparent Electrode by Forming Layer of Anode Material on Surface of Transparent Substrate

An inorganic oxide such as indium-tin oxide (ITO) or indium-zinc oxide (IZO), a metal such as gold, silver or aluminum, or an organic compound having high charge transportability, such as a polythiophene derivative or a polyaniline derivative, may be used as the anode material. Of these, ITO is most preferred. A substrate made of glass or a clear plastic may be used as the transparent substrate.

The method of forming the layer of anode material (anode layer) is suitably selected according to the nature of the anode material. When the material is difficult to dissolve, difficult to disperse and sublimable, a dry process such as vapor deposition or sputtering is generally selected. When it is a solution material or a dispersion material, the optimal method from among the various above-mentioned types of wet processes is employed while taking into account, for example, the viscosity and surface tension of the composition and the desired thickness of the thin film.

Alternatively, a commercial transparent anode substrate may be used. In this case, from the standpoint of increasing the device yield, the use of a substrate that has been subjected to smoothing treatment is preferred. When a commercial transparent anode substrate is used, the method of manufacturing the organic thin-film solar cell of the invention does not include an anode layer-forming step.

In cases where a transparent anode substrate is formed using an inorganic oxide such as ITO as the anode material, before depositing the top layer thereon, it is preferable to clean the substrate with, for example, a cleaning agent, alcohol or pure water. In addition, the anode substrate is preferably subjected to surface treatment such as UV/ozone treatment or oxygen-plasma treatment just prior to use. Surface treatment need not be carried out if the anode material is composed primarily of an organic substance.

### Formation of Hole Collecting Layer

### Step of Forming Hole Collecting Layer on Formed Layer of Anode Material

Using the inventive composition, a hole collecting layer is formed on the anode material layer in accordance with the above-described method.

### Formation of Active Layer

### Step of Forming Active Layer on Formed Hole Collecting Layer

The active layer may be obtained by stacking an n layer which is a thin film consisting of an n-type semiconductor material and a p layer which is a thin film consisting of a p-type semiconductor material, or may be a non-stacked thin film consisting of a mixture of these materials. Also, in this invention, a NFA active layer is formed as the active layer. As used herein, “NFA active layer” refers to an active layer in which the NFA content is more than 50 wt % of the n-type semiconductor included in the active layer. This content is preferably at least 70 wt %, more preferably at least 80 wt %, and even more preferably at least 90 wt %.

Examples of the n-type semiconductor material include the compounds of formulas (3-1) to (3-4) below.

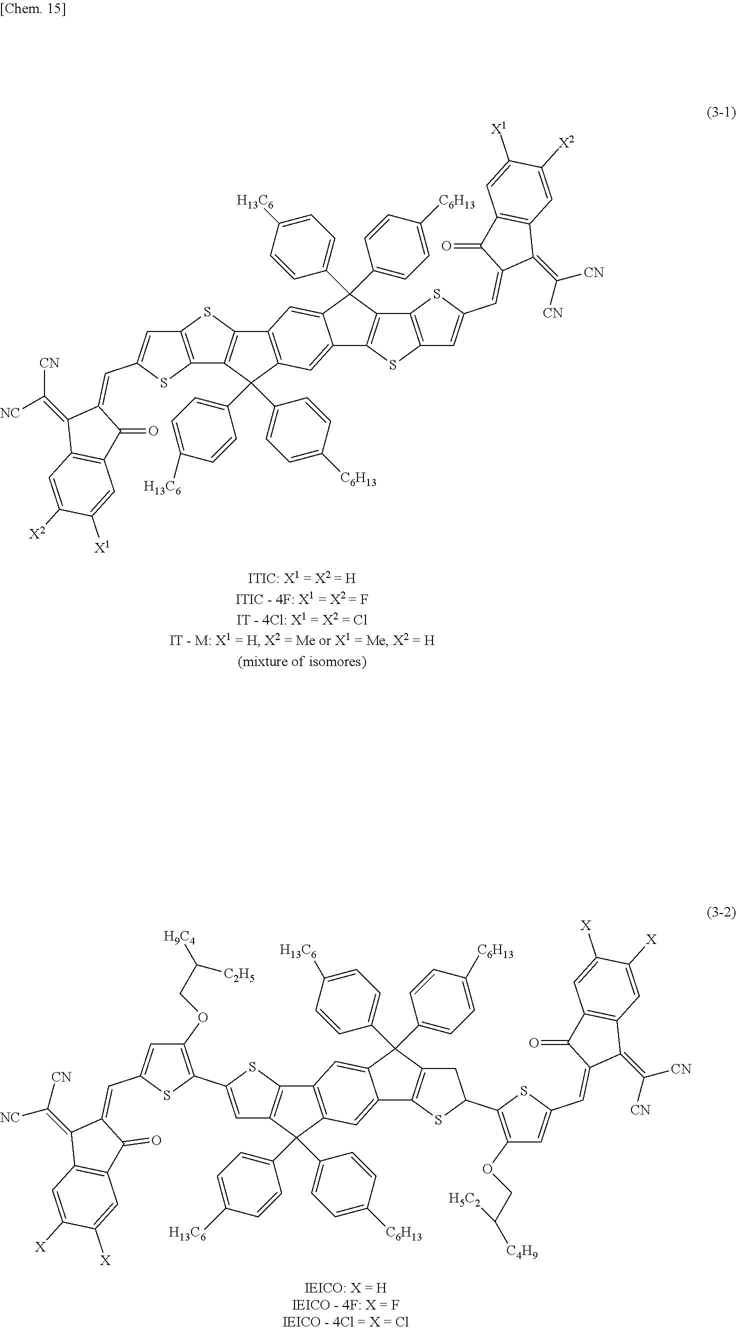

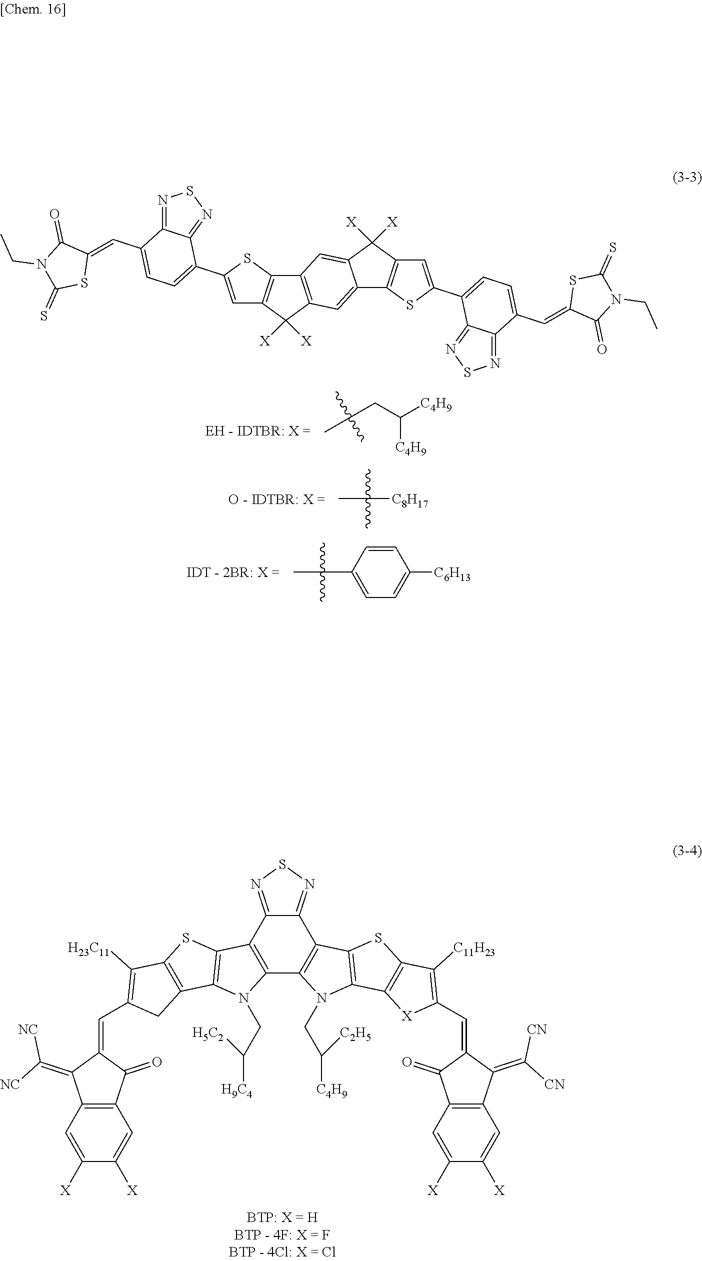

Examples of p-type semiconductor materials include polymers having a thiophene skeleton on the main chain, such as regioregular poly(3-hexylthiophene) (P3HT), PTB7 of formula (4-1) below, PM6 of formula (4-2) below (also known as PBDB-T-2F), and the thienothiophene unit-containing polymers mentioned in JP-A 2009-158921 and WO 2010/008672 A1; phthalocyanines such as CuPC and ZnPC; and porphyrins such as tetrabenzoporphyrin.

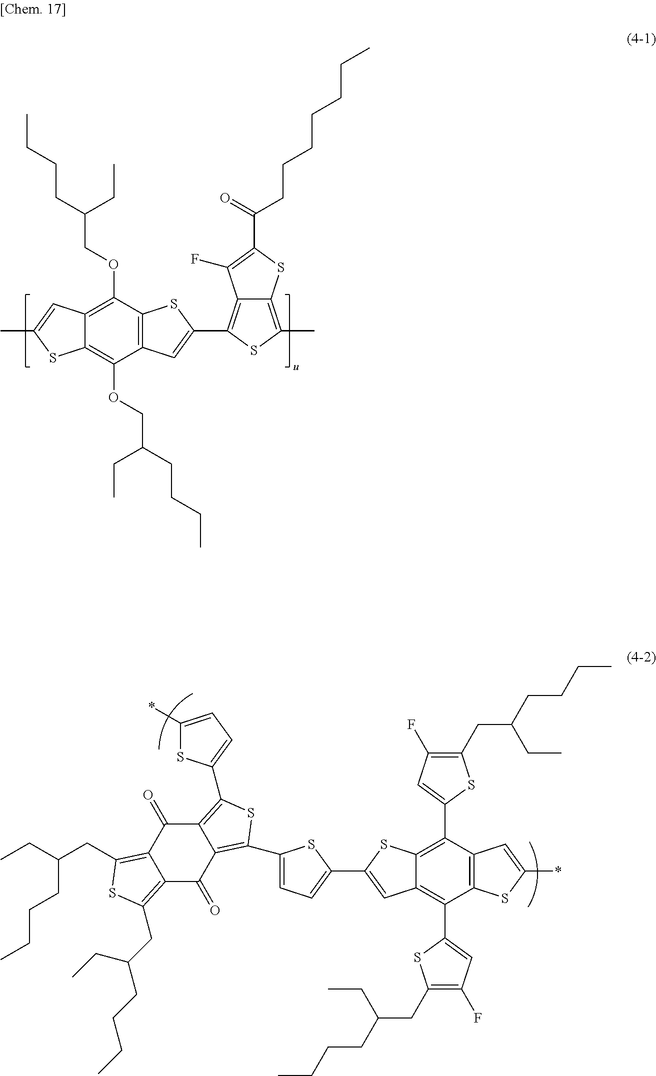

In the formulas, the subscript ‘u’ represents the number of repeating units, and * represents a site available for bonding,

Of these, the n-type semiconductor material is preferably a compound of formula (3-1), with ITIC-4F in which X¹ and X² are both fluorine being more preferred. The p-type semiconductor material is preferably a polymer having a thiophene skeleton on the main chain, such as PM6 and PTB7.

Here, “thiophene skeleton on the main chain” refers to a divalent aromatic ring consisting solely of thiophene, or a divalent condensed aromatic ring containing one or more thiophene, such as thienothiophene, benzothiophene, dibenzothiophene, benzodithiophene, naphthothiophene, naphthodithiophene, anthrathiophene and anthradithiophene. These may be substituted with halogen atoms, nitro groups, cyano groups, sulfonic groups, alkoxy groups of 1 to 20 carbon atoms, thioalkoxy groups of 1 to 20 carbon atoms, alkyl groups of 1 to 20 carbon atoms, alkenyl groups of 2 to 20 carbon atoms, alkynyl groups of 2 to 20 carbon atoms, haloalkyl groups of 1 to 20 carbon atoms, aryl groups of 6 to 20 carbon atoms, aralkyl groups of 7 to 20 carbon atoms or acyl groups of 1 to 20 carbon atoms.

The halogen atoms, alkyl groups of 1 to 20 carbon atoms, alkoxy groups of 1 to 20 carbon atoms, aryl groups of 6 to 20 carbon atoms and aralkyl groups of 7 to 20 carbon atoms are exemplified by the same groups as mentioned above.

Specific examples of thioalkoxy groups of 1 to 20 carbon atoms include groups in which the oxygen atoms on the alkoxy groups are substituted with sulfur atoms.

Specific examples of thioalkoxy (alkylthio) groups of 1 to 20 carbon atoms include methylthio, ethylthio, n-propylthio, isopropylthio, n-butylthio, isobutylthio, s-butylthio, t-butylthio, n-pentylthio, n-hexylthio, n-heptylthio, n-octylthio, n-nonylthio, n-decylthio, n-undecylthio, n-dodecylthio, n-tridecylthio, n-tetradecylthio, n-pentadecylthio, n-hexadecylthio, n-heptadecylthio, n-octadecylthio, n-nonadecyhhio and n-eicosanyithio groups.

Specific examples of alkenyl groups of 2 to 20 carbon atoms include ethenyl, n-1-propenyl, n-2-propenyl, 1-methylethenyl, n-1-butenyl, n-2-butenyl, n-3-butenyl, 2-methyl-1-propenyl, 2-methyl-2-propenyl, 1-ethylethenyl, 1-methyl-1-propenyl, 1-methyl-2-propenyl, n-1-pentenyl, n-1-decenyl and n-1-eicosenyl groups.

Specific examples of alkynyl groups of 2 to 20 carbon atoms include ethynyl, n-1-propynyl, n-2-propynyl, n-1-butynyl, n-2-butynyl, n-3-butynyl, 1-methyl-2-propynyl, n-1-pentynyl, n-2-pentynyl, n-3-pentynyl, n-4-pentynyl, 1-methyl-n-butynyl, 2-methyl-n-butynyl 3-methyl-n-butynyl, 1,1-dimethyl-n-propynyl, n-1-hexynyl, n-1-decynyl, n-1-pentadecynyl and n-1-eicosynyl groups.

Haloalkyl groups of 1 to 20 carbon atoms are exemplified by groups in which at least one hydrogen atom on the above alkyl groups is substituted with a halogen atom. The halogen atom may be a chlorine, bromine, iodine or fluorine atom. Of these, fluoroalkyl groups are preferred, and perfluoroalkyl groups are more preferred.

Specific examples include fluoromethyl, difluoromethyl, trifluoromethyl, pentafluoroethyl, 2,2,2-trifluoroethyl, heptafluoropropyl, 2,2,3,3,3-pentafluoropropyl, 2,2,3,3-tetraftuoropropyl, 2,2,2-trifluoro-2-(trifluoromethypethyl, nonafluorobutyl, 4,4,4-trifluorobutyl, undecafluoropentyl, 2,2,3,3,4,4,5,5,5-nonafluoropentyl, 2,2,3,3,4,4,5,5-octafluoropentyl, tridecafluorohexyl, 2,2,3,3,4,4,5,5,6,6,6-undecalluorohexyl, 2,2,3,3,4,4,5,5,6,6-decafluorohexyl and 3,3,4,4,5,5,6,6,6-nonafluorohexyl groups.

Specific examples of acyl groups of 1 to 20 carbon atoms include formyl, acetyl, propionyl, butyryl, isobutyryl, valeryl, isovaleryl and benzoyl groups.

n-Type semiconductor materials which are fullerene acceptors may be included as the balance of the n-type semiconductor material within a range of less than 50 wt % of the n-type semiconductor material included in the active layer, provided that doing so does not detract from the advantageous effects of the invention. Specific examples of such n-type semiconductor materials include fullerene, [6,6]-phenyl-C₆₁-butyric acid methyl ester (PC₆₁BM) and [6,6]-phenyl-C₇₁-butyric acid methyl ester (PC₇₁BM).

It is also possible to acquire the active layer composition used in the NFA active layer as a commercial product.

Examples of such commercial products include PV-X Plus and PV-ATL-D1A1, both from Raynergy Tek Inc.

In the same way as above, the method of forming an active layer is selected from among the various aforementioned dry processes when the active layer material is a material that is difficult to dissolve and sublimable. When it is a solution material or a dispersion material, the optimal method from among the various types of aforementioned wet processes is employed while taking into account, for example, the viscosity and surface tension of the composition and the desired thickness of the thin film.

### Formation of Electron Collecting Layer

### Step of Forming Electron Collecting Layer on Formed Active Layer

Where necessary, an electron collecting layer may be formed between the active layer and the cathode layer in order to, for example, make charge transfer more efficient.

Illustrative examples of electron collecting layer-forming materials include lithium oxide (Li₂O), magnesium oxide (MgO), alumina (Al₂O₃), lithium fluoride (LiF), sodium fluoride (NaF), magnesium fluoride (MgF₂), strontium fluoride (SrF₂), cesium carbonate (Cs₂CO₃), lithium 8-quinolinolate (Liq), sodium 8-quinolinolate (Nag), bathocuproin (BCP), 4,7-diphenyl-1,10-phenanthroline (BPhen), polyethyleneimine (PEI) and ethoxylated polyethyleneimine (PEIE).

In the same way as above, the method of forming an electron collecting layer is selected from among the various aforementioned thy processes when the electron collecting material is a material that is difficult to dissolve and sublimable. When it is a solution material or a dispersion material, the optimal method from among the various types of aforementioned wet processes is employed while taking into account, for example, the viscosity and surface tension of the composition and the desired thickness of the thin film.

### Formation of Cathode Layer

### Step of Forming Cathode Layer on Formed Electron Collecting Layer

Illustrative examples of cathode materials include metals such as aluminum, magnesium-silver alloys, aluminum-lithium alloys, lithium, sodium, potassium, cesium, calcium, barium, silver and gold; inorganic oxides such as indium tin oxide (ITO) and indium zinc oxide (IZO); and organic compounds having high charge transportability, such as polythiophene derivatives and polyaniline derivatives. A plurality of cathode materials may be used by stacking or by mixing them together.

In the same way as above, the method of forming a cathode layer is selected from among the various aforementioned dry processes when the cathode layer material is a material that is difficult to dissolve, difficult to disperse and sublimable. When it is a solution material or a dispersion material, the optimal method from among the various types of aforementioned wet processes is employed while taking into account, for example, the viscosity and surface tension of the composition and the desired thickness of the thin film.

### Formation of Carrier Blocking Layers

Where necessary, carrier blocking layers may be provided between desired layers for such purposes as to control the rectifiability of the photoelectric current. When carrier blocking layers are provided, it is common to insert an electron blocking layer between the active layer and the hole collecting layer or the anode, and to insert a hole blocking layer between the active layer and the electron collecting layer or the cathode, although the invention is not limited in this regard.

Examples of hole blocking layer-forming materials include titanium oxide, zinc oxide, tin oxide, bathocuproin (BCP) and 4,7-diphenyl-1,10-phenanthroline (BPhen).

Examples of electron blocking layer-forming materials include triarylamine materials such as N,N′-di(1-naphthyl)-N,N′-diphenylbenzidine (α-NPD) and poly(triarylamine) (PTAA).

In the same way as mentioned above, the method of forming carrier blocking layers is selected from among the various aforementioned dry processes when the carrier blocking layer material is a material that is difficult to dissolve, difficult to disperse and sublimable. When it is a solution material or a dispersion material, the optimal method from among the various types of aforementioned wet processes is employed while taking into account, for example, the viscosity and surface tension of the composition and the desired thickness of the thin film.

### (2) Inverted Stack-Type Organic Thin-Film Solar Cell

### Formation of Cathode Layer

### Step of Producing Transparent Cathode Substrate by Forming Layer of Cathode Material on Surface of Transparent Substrate

The cathode material is exemplified by, in addition to the anode materials mentioned above for a normal stack-type organic thin-film solar cell, fluorine-doped tin oxide (FTO). The transparent substrate is exemplified by the anode materials mentioned above for a normal stack-type organic thin film solar cell.

The method of forming a layer of cathode material (cathode layer) is selected from among the aforementioned dry processes when the cathode material is difficult to dissolve, difficult to disperse and sublimable, When it is a solution material or a dispersion material, the optimal method from among the various types of aforementioned wet processes is employed while taking into account, for example, the viscosity and surface tension of the composition and the desired thickness of the thin film.

Alternatively, a commercial transparent cathode substrate may be used in this case. From the standpoint of increasing the device yield, the use of a substrate that has been subjected to smoothing treatment is preferred. When a commercial transparent cathode substrate is used, the method of manufacturing the organic thin-film solar cell of the invention does not include a cathode layer-forming step.

In cases where the transparent cathode substrate is formed using an inorganic oxide as the cathode material, cleaning treatment and surface treatment similar to that employed for the anode material in a normal stack-type organic thin-film solar cell may be carried out.

### Formation of Electron-Collecting Layer

### Step of Forming Electron Collecting Layer on Formed Cathode

If necessary, an electron collecting layer may be formed between the active layer and the cathode layer in order to, for example, make charge transfer more efficient.

Illustrative examples of electron collecting layer-forming materials include, in addition to the materials mentioned above for a normal stack-type organic thin-film solar cell, zinc oxide (ZnO), titanium oxide (TiO) and tin oxide (SnO).

The method of forming the electron collecting layer is selected from among the above dry processes in cases where this material is difficult to dissolve, difficult to disperse and sublimable. When it is a solution material or a dispersion material, the optimal method from among the various types of aforementioned wet processes is employed while taking into account, for example, the viscosity and surface tension of the composition and the desired thickness of the thin film. Alternatively, a method may be employed which uses a wet process (especially spin coating or slit coating) to form an inorganic oxide precursor layer on the cathode, and then bakes the precursor layer to form an inorganic oxide layer.

### Formation of Active Layer

### Step of Forming Active Layer on Formed Electron Collecting Layer

The active layer may be obtained by stacking an n layer that is a thin film consisting of an n-type semiconductor material and a p layer that is a thin film consisting of a p-type semiconductor material, or may be a non-stacked thin film consisting of a mixture of these materials.

The n-type and p-type semiconductor materials are exemplified by the same materials as mentioned above as semiconductor materials for a normal stack-type device, although ITIC-4F is preferred as the n-type material, and polymers having a thiophene skeleton on the main chain, such as PM6 and PTB7, are preferred as the p-type material.

The method of forming the active layer is similar to the method described above for the active layer in a normal stack-type device.

### Formation of Hole Collecting Layer

### Step of Forming Hole Collecting Layer on Formed Active Layer

Using the inventive composition, a hole collecting layer is formed on the layer of active material in accordance with the above method.

### Formation of Anode Layer

### Step of Forming Anode Layer on Formed Hole Collecting Layer

The anode material is exemplified in the same way as the aforementioned anode material for a normal stack-type device. The method of forming an anode layer is similar to that used to form the cathode layer in a normal stack-type device.

### Formation of Carrier-Blocking Layers

As with a normal stack-type device, where necessary, carrier blocking layers may to be provided between desired layers for such purposes as to control the rectifiability of the photoelectric current.

The hole blocking layer-forming material and the electron blocking layer-forming material are exemplified in the same way as above, and the methods of forming the carrier blocking layers are also the same as above.

To prevent device deterioration from exposure to the atmosphere, an OPV device that has been manufactured by the illustrative method described above can be again placed in a glovebox, sealed in a nitrogen or other inert gas atmosphere and, in the sealed state, made to function as a solar cell or measurement of the solar cell characteristics carried out.

The sealing method may be, for example, a method in which a concave glass substrate with a UV-curable resin attached to the edges is bonded to the film-forming side of the organic thin-film solar cell device and the resin is cured by UV irradiation, all within an inert gas atmosphere, or a method in which film sealing is carried out in a vacuum by a technique such as sputtering.

### EXAMPLES

Examples of the invention and Comparative Examples are given below to more concretely illustrate the invention, although the invention is not limited by these Examples. The equipment used was as follows.
(1) Glovebox: VAC glov box system, from Yamahachi &Co., Ltd.
(2) Vapor Deposition System: A vacuum deposition system from Aoyama Engineering KK
(3) Solar Simulator: OTENTOSUN-III, AM 1.5 G filter; radiation intensity, 100 mW/cm²; from Bunkoukeiki Co., Ltd.
(4) Source Measurement Unit: 2612A, from Keithley Instruments KK
(5) Measurement of Ionization Potential AC-3, from Riken Keiki Co., Ltd.

### [1] Preparation of Active Layer Compositions

### Preparation Example 1

Chlorobenzene (2.5 mL) and 12.5 μL of 1,8-diiodooctane (available from Tokyo Chemical Industry Co., Ltd.) were added to a sample vial containing 25 mg of PBDB-T-2F (Sigma-Aldrich, Inc.) and 25 mg of ITIC-4F (Sigma Aldrich, Inc.), and the vial contents were stirred for 15 hours on a hot plate set to 70° C. The resulting solution was allowed to cool to room temperature, giving Solution A1 (an active layer composition).

### Preparation Example 2

Chlorobenzene (2.0 mL) was added to a sample vial containing 20 mg of PTB7 (available from 1-Material) and 30 mg of PC₆₁BM (available from Frontier Carbon Corporation under the product name “nanom spectra E100”), and the vial contents were stirred for 15 hours on a hot plate set to 80° C. The resulting solution was allowed to cool to room temperature, following which 10 −L of 1,8-diiodooctane (Tokyo Chemical Industry Co., Ltd.) was added and stirring was carried out, giving Solution A2 (an active layer composition).

### Preparation Example 3

Chlorobenzene (2.0 mL) was added to a sample vial containing 20 mg of PTB7 (available from 1-Material) and 30 mg of PC₆₁BM (available from Frontier Carbon Corporation under the product name “nanom spectra E100”), and the vial contents were stirred for 15 hours on a hot plate set to 80° C. The resulting solution was allowed to cool to room temperature, following which 60 μL of 1,8-diiodooctane (Tokyo Chemical Industry Co., Ltd.) was added and stirring was carried out, giving Solution A3 (an active layer composition).

### [2] Production of Hole Collecting Layer-Forming Compositions

### Example 1-1

Arylsulfonic Acid Compound A of above formula (2-1) synthesized based on the description in WO 2006/025342 A1 was added in an amount of 5.05 mg to a solution obtained by the addition of 2.47 g of isopropanol to 2.53 g of SELFTRON (available as SELFTRON S from Tosoh Corporation; 2.0 wt % aqueous solution), thereby preparing a deep blue solution having a concentration of 1.1 wt %. The resulting deep blue solution was filtered with a syringe filter having a pore size of 0.45 μm, giving Hole Collecting Layer-Forming Composition B1.

### Example 1-2

Arylsulfonic Acid Compound A of above formula (2-1) synthesized based on the description in WO 2006/025342 A1 was added in an amount of 25.3 mg to a solution obtained by the addition of 2.50 g of isopropanol to 2.53 g of SELFTRON (available as SELFTRON S from Tosoh Corporation; 2.0 wt % aqueous solution), thereby preparing a deep blue solution having a concentration of 1.5 wt %. The resulting deep blue solution was filtered with a syringe filter having a pore size of 0.45 μm, giving Hole Collecting Layer-Forming Composition B2.

### Example 1-3

Arylsulfonic Acid Compound A of above formula (2-1) synthesized based on the description in WO 2006/025342 A1 was added in an amount of 50.2 mg to a solution obtained by the addition of 2.45 g of isopropanol to 2.49 g of SELFTRON (available as SELFTRON S from Tosoh Corporation; 2.0 wt % aqueous solution), thereby preparing a deep blue solution having a concentration of 2.0 wt %. The resulting deep blue solution was filtered with a syringe filter having a pore size of 0.45 μm, giving Hole Collecting Layer-Forming Composition B3.

### Example 1-4

12 Molybdo(IV) phosphoric acid n hydrate (Fujifilm Wako Pure Chemical Corporation) was added in an amount of 5.03 mg to a solution obtained by the addition of to 2.48 g of isopropanol to 2.54 g of SELFTRON (available as SELFTRON S from Tosoh Corporation; 2.0 wt % aqueous solution), thereby preparing a deep blue solution having a concentration of 1.1 wt %. The resulting deep blue solution was filtered with a syringe filter having a pore size of 0.45 μm, giving Hole Collecting Layer-Forming Composition B4.

### Example 1-5

12 Molybdo(IV) phosphoric acid n hydrate (Fujifilm Wako Pure Chemical Corporation) was added in an amount of 24.9 mg to a solution obtained by the addition of 2.47 g of isopropanol to 2.53 g of SELFTRON (available as SELFTRON S from Tosoh Corporation; 2.0 wt % aqueous solution), thereby preparing a deep blue solution having a concentration of 1.5 wt %. The resulting deep blue solution was filtered with a syringe filter having a pore size of 0.45 μm, giving Hole Collecting Layer-Forming Composition B5.

### Example 1-6

12 Molybdo(IV) phosphoric acid n hydrate (Fujifilm Wako Pure Chemical Corporation) was added in an amount of 50.0 mg to a solution obtained by the addition of 2.46 g of isopropanol to 2.52 g of SELFTRON (available as SELFTRON S from Tosoh Corporation; 2.0 wt % aqueous solution), thereby preparing a deep blue solution having a concentration of 2.0 wt %. The resulting deep blue solution was filtered with a syringe filter having a pore size of 0.45 μm, giving Hole Collecting Layer-Forming Composition B6.

### Example 1-7

Arylsulfonic Acid Compound A of above formula (2-1) synthesized based on the description in WO 2006/025342 A1, in an amount of 26.9 mg, and 26.9 mg of 12 molybdo(IV) phosphoric acid n hydrate (Fujifilm Wako Pure Chemical Corporation) were added to a solution obtained by the addition of 2.64 g of isopropanol to 2.68 g of SELFTRON (available as SELFTRON S from Tosoh Corporation 2.0 wt % aqueous solution), thereby preparing a deep blue solution having a concentration of 2.0 wt %. The resulting deep blue solution was filtered with a syringe filter having a pore size of 0.45 μm, giving Hole Collecting Layer-Forming Composition B7.

### Example 1-8

An aqueous solution of 18.7 mg of Arylsulfonic Acid Compound A of above formula (2-1) synthesized based on the description in WO 2006/025342 A1 and 18.9 mg of 12 molybdo(IV) phosphoric acid n hydrate (Fujifilm Wako Pure Chemical Corporation) dissolved in 3.6 g of pure water was added to 3.6 g of an aqueous PEDOT/PSS solution (HTL Solar, from Heraeus; 1.0 wt % aqueous dispersion), thereby preparing a deep blue solution having a concentration of 1.0 wt %. The resulting deep blue solution was filtered with a syringe filter having a pore size of 1.00 μm, giving Hole Collecting Layer-Forming Composition B8.

### Example 1-9

Arylsulfonic Acid Compound A of above formula (2-1) synthesized based on re description in WO 2006/025342 A1 was added in an amount of 5.05 mg to a solution obtained by the addition of 2.48 g of isopropanol and 1.5 mg of the fluorinated nonionic surfactant F-559 (DIC Corporation) to 2.52 g of SELFTRON (available as SELFTRON S from Tosoh Corporation; 2.0 wt % aqueous solution), thereby preparing a deep blue solution having a concentration of 1.1 wt %. The resulting deep blue solution was filtered with a syringe filter having a pore size of 0.45 μm, giving Hole Collecting Layer-Forming Composition B9.

### Example 1-10

Arylsulfonic Acid Compound A of above formula (2-1) synthesized based on the description in WO 2006/025342 A1 was added in an amount of 25.05 mg to a solution obtained by the addition of 2.46 g of isopropanol and 1.5 mg of the fluorinated nonionic surfactant F-559 (DIC Corporation) to 2.51 g of SELFTRON (available as SELFTRON S from Tosoh Corporation; 2.0 wt % aqueous solution), thereby preparing a deep blue solution having a concentration of 1.5 wt %. The resulting deep blue solution was filtered with a syringe filter having a pore size of 0.45 μm, giving Hole Collecting Layer-Forming Composition B10.

### Example 1-11

Arylsulfonic Acid Compound A of above formula (2-1) synthesized based on the description in WO 2006/025342 A1 was added in an amount of 49.05 mg to a solution obtained by the addition of 2.47 g of isopropanol and 1.5 mg of the fluorinated nonionic surfactant F-559 (DEC Corporation) to 2.48 g of SELFTRON (available as SELFTRON S from Tosoh Corporation; 2.0 wt % aqueous solution), thereby preparing a deep blue solution having a concentration of 2.0 wt %. The resulting deep blue solution was filtered with a syringe filter having a pore size of 0.45 μm, giving Hole Collecting Layer-Forming Composition B11.

### Example 1-12

Arylsulfonic Acid Compound A of above formula (2-1) synthesized based on the description in WO 2006/025342 A1, in an amount of 25.05 mg. and 25.05 mg of 12 molybdo(IV) phosphoric acid n hydrate (Fujifilm Wako Pure Chemical Corporation) were added to a solution obtained by the addition of 2.46 g of isopropanol and 1.5 mg of the fluorinated nonionic surfactant F-559 DIC Corporation) to 2.53 g of SELFTRON (available as SELFTRON S from Tosoh Corporation; 2.0 wt % aqueous solution), thereby preparing a deep blue solution having a concentration of 2.0 wt %. The resulting deep blue solution was filtered with a syringe filter having a pore size of 0.45 μm, giving Hole Collecting Layer-Forming Composition B12.

### Example 1-13

Atylsulfonic Acid Compound A of above formula (2-1) synthesized based on the description in WO 2006/025342 A1, in an amount of 25.0 mg, and 7.50 mg of silicomolybdic acid n hydrate (Fujifilm Wako Pure Chemical Corporation) were added to a solution obtained by the addition of 3.71 g of pure water, 5.00 mg of the fluorinated nonionic surfactant (FN-1287 (DKS Co., Ltd.) and 1.00 mg of the fluorinated nonionic surfactant F-559 (DIC Corporation) to 1.25 g of SELFTRON (available as SELFTRON S from Tosoh Corporation; 2.0 wt % aqueous solution), thereby preparing a deep blue solution having a concentration of 1.15 wt %. The resulting deep blue solution was filtered with a syringe filter having a pore size of 0.45 jtm, giving Hole Collecting Layer-Forming Composition B13.

### Example 1-14

Arylsulfonic Acid Compound A of above formula (2-1) synthesized based on the description in WO 2006/025342 A1, in an amount of 25.0 mg, and 7.50 mg of silicotungstic acid n hydrate (from Alfa Aesar KK) were added to a solution obtained by the addition of 3.71 g of pure water, 5.00 mg of the fluorinated nonionic surfactant FN-1287 (DKS Co., Ltd.) and 1.00 mg of the fluorinated nonionic surfactant F-559 (DIC Corporation) to 1.25 g of SELFTRON (available as SELFTRON S from Tosoh Corporation; 2.0 wt % aqueous solution), thereby preparing a deep blue solution having a concentration of 1.15 wt %. The resulting deep blue solution was filtered with a syringe filter having a pore size of 0.45 μm, giving Hole Collecting Layer-Forming Composition B14.

### Example 1-15

Arylsulfonic Acid Compound A of above formula (2-1) synthesized based on the description in WO 2006/025342 A1, in an amount of 3.0 mg, and 3.0 mg of 12 molybdo(IV) phosphoric acid n hydrate (Fujifilm Wako Pure Chemical Corporation) were added to 2.99 g of an aqueous PEDOT/PSS solution (HTL Solar, from Heraeus, 1.0 wt % aqueous dispersion), thereby preparing a deep blue solution having a concentration of 1.2 wt %. The resulting deep blue solution was filtered with a syringe filter having a pore size of 1.00 μm, giving Hole Collecting Layer-Forming Composition B15.

### Comparative Example 1-1

Isopropanol (2.47 g) and 1.5 mg of the fluorinated nonionic surfactant F-559 (DIC Corporation) were added to 2.52 g of SELFTRON (available as SELFTRON S from Tosoh Corporation; 2.0 wt % aqueous solution), thereby preparing a deep blue solution having a concentration of 1.0 wt %. The resulting deep blue solution was filtered with a syringe filter having a pore size of 0.45 μm, giving Hole Collecting Layer-Forming Composition C1.

### Comparative Example 1-2

Pure water (3.71 g), 5.00 mg of the fluorinated nonionic surfactant FN-1287 (DKS Co., Ltd.) and 1.00 mg of the fluorinated nonionic surfactant F-559 (DIC Corporation) were added to 1.25 g of SELFTRON (available as SELFTRON S from Tosoh Corporation; 2.0 wt % aqueous solution), thereby preparing a deep blue solution having a concentration of 1.0 wt %. The resulting deep blue solution was filtered with a syringe filter having a pore size of 0.45 μm, giving Hole Collecting Layer-Forming Composition C2.

### Comparative Example 1-3

An aqueous PEDOT/PSS solution (HTL Solar, from Heraeus; 1.0 wt % aqueous dispersion) was filtered with a syringe filter having a pore size of 1.00 μm, giving Hole Collecting Layer-Forming Composition C3.

### [3] Production of Hole Collecting Layer-Forming Composition-Coated Substrate for Ionization Potential Measurement

### Example 2-1

A 20 mm×20 mm glass substrate with an ITO transparent conductive layer thereon was UV/ozone treated for 15 minutes, Hole Collecting Layer-Forming Composition B1 prepared in Example 1-1 was applied onto this substrate by spin coating and annealing treatment was subsequently carried out by 5 minutes of heating at 100° C., thereby producing a hole collecting layer-forming composition-coated substrate.

### Example 2-2

Aside from using Hole Collecting Layer-Forming Composition B2 instead of Hole Collecting Layer-Forming Composition B1, a hole collecting layer-forming composition-coated substrate was produced in the same way as in Example 2-1.

### Example 2-3

Aside from using Hole Collecting Layer-Forming Composition B3 instead of Hole Collecting Layer-Forming Composition B1, a hole collecting layer-forming to composition-coated substrate was produced in the same way as in Example 2-1.

### Example 2-4

Aside from using Hole Collecting Layer-Forming Composition B4 instead of Hole Collecting Layer-Forming Composition B1, a hole collecting layer-forming composition-coated substrate was produced in the same way as in Example 2-1.

### Example 2-5

Aside from using Hole Collecting Layer-Forming Composition B5 instead of Hole Collecting Layer-Forming Composition B1, a hole collecting layer-forming composition-coated substrate was produced in the same way as in Example 2-1.

### Example 2-6

Aside from using Hole Collecting Layer-Forming Composition B6 instead of Hole Collecting Layer-Forming Composition B1, a hole collecting layer-forming composition-coated substrate was produced in the same way as in Example 2-1.

### Example 2-7

Aside from using Hole Collecting Layer-Forming Composition B7 instead of Hole Collecting Layer-Forming Composition B1, a hole collecting layer-forming composition-coated substrate was produced in the same way as in Example 2-1.

### Example 2-8

Aside from using Hole Collecting Layer-Forming Composition 313 instead of Hole Collecting Layer-Forming Composition B1, a hole collecting layer-forming composition-coated substrate was produced in the same way as in Example 2-1.

### Example 2-9

Aside from using Hole Collecting Layer-Forming Composition B14 instead of Hole Collecting Layer-Forming Composition B1, a hole collecting layer-forming to composition-coated substrate was produced in the same way as in Example 2-1.

### Example 2-10

Aside from using Hole Collecting Layer-Forming Composition B8 instead of Hole Collecting Layer-Forming Composition B1, a hole collecting layer-forming composition-coated substrate was produced in the same way as in Example 2-1.

### Comparative Example 2-1

Aside from using Hole Collecting Layer-Forming Composition C1 instead of Hole Collecting Layer-Forming Composition B1, a hole collecting layer-forming composition-coated substrate was produced in the same way as in Example 2-1.

### Comparative Example 2-2

Aside from using Hole Collecting Layer-Forming Composition C2 instead of Hole Collecting Layer-Forming Composition B1, a hole collecting layer-forming composition-coated substrate was produced in the same way as in Example 2-1.

### Comparative Example 2-3

Aside from using Hole Collecting Layer-Forming Composition C3 instead of Hole Collecting Layer-Forming Composition B1, a hole collecting layer-forming composition-coated substrate was produced in the same way as in Example 2-1.

### [4] Measurement of Ionization Potential

Using an apparatus for measuring ionization potential, ionization potential (Ip) measurements were carried out on the hole collecting layer-forming composition-coated substrates produced in Examples 2-1 to 2-10 and Comparative Examples 2-1 to 2-3. Measurement was carried out at a light intensity setting of 20.0 nW and 0.1 eV intervals in the energy range of 4.00 to 6.00 eV, and the Ip was determined from the photoelectron emission threshold energy.

TABLE 1

| | Ink No. | Ip (eV) |
|---|---|---|
| Example 2-1 | B1 | 5.1 |
| Example 2-2 | B2 | 5.2 |
| Example 2-3 | B3 | 5.2 |
| Example 2-4 | B4 | 5.1 |
| Example 2-5 | B5 | 5.2 |
| Example 2-6 | B6 | 5.3 |
| Example 2-7 | B7 | 5.4 |
| Example 2-8 | B13 | 5.6 |
| Example 2-9 | B14 | 5.6 |
| Example 2-10 | B8 | 5.5 |
| Comparative Example 2-1 | C1 | 5.0 |
| Comparative Example 2-2 | C2 | 5.0 |
| Comparative Example 2-3 | C3 | 5.2 |

As shown in Table 1, on comparing Comparative Example 2-1 with each of Examples 2-1 to 2-3 and Examples 2-4 to 2-6, the Ip was found to deepen with an increase in the added amount of additives. On comparing Examples 2-3 and 2-6 with Example 2-7, even at the same amount of addition, a deeper Ip was obtained with the addition of two types of additive. From Examples 2-8 and 2-9, these effects were confirmed to arise not only with a phosphoric acid-based heteropolyacid, but even with a silicic acid-based heteropolyacid. A similar effect was confirmed also from a comparison of Comparative Example 2-3 with Example 2-10.

It is thus apparent that the Ip can more effectively deepened by including two types of additive.

### [4] Fabrication of Organic Thin-Film Solar Cell

### Example 3-1

A 25 mm×25 mm glass substrate patterned thereon with, as the anode, an ITO transparent conductive layer in the form of 10 mm×25 mm stripes was UV/ozone treated for 15 minutes. An electron collecting layer-forming zinc oxide solution (from Genes' Ink) was added dropwise and spin-coated onto this substrate to form a film. The resulting electron collecting layer had a film thickness of about 30 nm. Next, within a fdovebox purged with an inert gas, Solution A1 obtained in Preparation Example 1 was added dropwise and spin-coated onto the resulting electron collecting layer, thereby forming an active layer.

Hole Collecting Layer-Forming Composition B9 prepared in Example 1-9 was then spin-coated onto this active layer, following which annealing treatment was carried out by minutes of heating at 100° C., thereby forming a hole collecting layer. The hole collecting layer had a film thickness of about 150 nm.

Finally, the stacked substrate was set within a vacuum vapor deposition system, the interior of the system was evacuated to a vacuum of 1×10⁻³ Pa or less, and a silver layer was vapor deposited to a thickness of 100 nm as the anode, thereby producing an inverted stack-type OPV device in which the surface area of regions where the striped ITO layer and the silver layer intersect is 10 mm×10 mm.

### Example 3-2

Aside from using Hole Collecting Layer-Forming Composition B10 instead of Hole Collecting Layer-Forming Composition B9, an inverted stack-type OPV device was fabricated in the same way as in Example 3-1.

### Example 3-3

Aside from using Hole Collecting Layer-Forming Composition B11 instead of Hole Collecting Layer-Forming Composition B9, an inverted stack-type OPV device was to fabricated in the same way as in Example 3-1.

### Example 3-4

Aside from using Hole Collecting Layer-Forming Composition B12 instead of Hole Collecting Layer-Forming Composition B9, an inverted stack-type OPV device was fabricated in the same way as in Example 3-1.

### Example 3-5

Aside from using Hole Collecting Layer-Forming Composition B15 instead of Hole Collecting Layer-Forming Composition B9, an inverted stack-type OPV device was fabricated in the same way as in Example 3-1.

### Example 3-6

Aside from using the NFA active layer PV-X Plus (from Raynergy tek) instead of Active Layer Composition A1 and using Hole Collecting Layer-Forming Composition B13 instead of Hole Collecting Layer-Forming Composition B9, an inverted stack-type OPV device was fabricated in the same way as in Example 3-1.

### Example 3-7

Aside from using Hole Collecting Layer-Forming Composition B14 instead of Hole Collecting Layer-Forming Composition B13, an inverted stack-type OPV device was fabricated in the same way as in Example 3-6.

### Comparative Example 3-1

Aside from using Hole Collecting Layer-Forming Composition C1 instead of Hole Collecting Layer-Forming Composition B9, an inverted stack-type OPV device was fabricated in the same way as in Example 3-1.

### Comparative Example 3-2

Aside from using Hole Collecting Layer-Forming Composition C3 instead of Hole Collecting Layer-Forming Composition B9, an inverted stack-type OPV device was to fabricated in the same way as in Example 3-1.

### Comparative Example 3-3

Aside from using Hole Collecting Layer-Forming Composition C2 instead of Hole Collecting Layer-Forming Composition B9, an inverted stack-type OPV device was fabricated in the same way as in Example 3-6.

### Comparative Example 3-4

Aside from using Active Layer Composition A2 instead of Active Layer Composition A1, an inverted stack-type OPV device was fabricated in the same way as in Example 3-5.

### Comparative Example 3-5

Aside from using Active Layer Composition A3 instead of Active Layer Composition A1, an inverted stack-type OPV device was fabricated in the same way as in Example 3-2.

### [5] Evaluation of Properties

The short-circuit current density Jsc (mA/cm²), open-circuit voltage Voc (V), fill factor FF and photoelectric conversion efficiency PCE (%) of the respective OPV devices fabricated in Examples 3-1 to 3-7 and Comparative Examples 3-1 to 3-3 were evaluated. The results are shown in Table 2.

The PCE (%) was computed as follows.

PCE(%)=Jsc(mA/cm²)×Voc(V)×FF±incident light intensity(100 mW/cm²)×100

TABLE 2

| | Active | Ink. | J_{SC} | V_{OC} | |
|---|---|---|---|---|---|
| | layer | No. | (mA/cm²) | (V) | FF |
| Example 3-1 | PBDB-T- | B9 | 9.0 | 0.66 | 0.46 |
| Example 3-2 | 2F/ITIC-F | B10 | 9.0 | 0.81 | 0.52 |
| Example 3-3 | | B11 | 10.0 | 0.81 | 0.50 |
| Example 3-4 | | B12 | 9.5 | 0.82 | 0.58 |
| Example 3-5 | | B15 | 10.8 | 0.75 | 0.52 |
| Example 3-6 | PV-X Plus | B13 | 19.6 | 0.80 | 0.53 |
| Example 3-7 | | B14 | 20.2 | 0.80 | 0.53 |
| Comparative Example 3-1 | PBDB-T- | C1 | 10.3 | 0.57 | 0.43 |
| Comparative Example 3-2 | 2F/ITIC-F | C3 | 11.3 | 0.60 | 0.46 |
| Comparative Example 3-3 | PV-X Plus | C2 | 14.5 | 0.71 | 0.48 |

As shown in Table 2, on comparing Comparative Example 3-1 with Examples 3-1 to 3-3, the V_{OC} was found to rise with an increase in the added amount of additive. Also, on comparing Example 3-3 with Example 3-4, even at the same amount of addition, a higher V_{OC} was obtained with the combined use of two types of electron accepting dopant substances. These results correlate well with the Ip results shown in Table 1. In addition, a high FF was obtained in Example 3-4, as a result of which the conversion efficiency also exhibits a high value. Although the reason for this is not entirely clear, it is conjectured that the two types of additives also increase the electron blocking properties. From Examples 3-6 and 3-7 and Comparative Example 3-3, these effects were confirmed not only with a phosphoric acid-based heteropolyacid, but also with a silicic acid-based heteropolyacid. Also, on comparing Comparative Example 3-2 with Example 3-5, increases in V_{OC} and FF were confirmed with the addition of two types of electron accepting dopant substances in the same way as in Example 3-4. These results demonstrated that, by using together two types of electron accepting dopant substances, addition effects can be obtained in a broad range of polythiophene derivatives.

On the other hand, the V_{OC} in Comparative Examples 3-3 and 3-4 were respectively 0.74 V and 0.76 V, and so a rise in V_{OC} with deepening of the Ip in the hole collecting layer was not confirmed. This suggests that the HOMO level of the FA active layer and the Ip of the hole collecting layer coincide even without the addition of an electron-accepting dopant, and so a further rise in V_{OC} with Ip deepening cannot be expected. That is, the present invention can be regarded as a hole collecting layer-forming composition which, in an NFA active layer capable of achieving a higher V_{OC} than a FA active layer, is suitable for lowering the energy gap between the HOMO level of the active layer and the Ip of the to hole-collecting layer and obtaining a high V_{OC}.

From the above results, it can be concluded that the combined use of two types of electron-accepting dopant substances deepens the Ip in a broad range of polythiophene derivatives, raises the V_{OC} of OPVs that use a NFA active layer, provides an increased FF accompanying the rise in electron blocking properties and elevates the conversion efficiency.

1. A charge transporting composition for forming a charge transporting thin film in a photovoltaic device having a non-fullerene active layer, the composition comprising a charee-transportine substance comprised of a polythiophene derivative having repeating units of formula (1) below 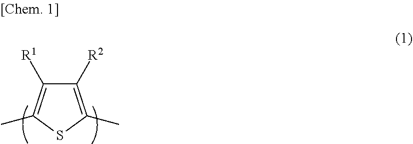
(wherein R¹ and R² are each independently a hydrogen atom, an alkyl group of 1 to 40 carbon atoms, a fluoroalkyl group of 1 to 40 carbon atoms, an alkoxy group of 1 to 40 carbon atoms, a fluoroalkoxy group of 1 to 40 carbon atoms, an aryloxy group of 6 to 20 carbon atoms, —O—[Z—O]ₚ—R^{e}, a sulfonic group or a sulfonate group, or R¹ and R² are bonded together to form —O—Y—O—; Y is an alkylene group of 1 to 40 carbon atoms which may include an ether bond and may be substituted with a sulfonic group or a sulfonate group; Z is an alkylene group of 1 to 40 carbon atoms which may be substituted with a halogen atom; p is an integer of 1 or more; and R^{e} is a hydrogen atom, an alkyl group of 1 to 40 carbon atoms which may be substituted with a sulfonic group or a sulfonate group, a fluoroalkyl group of 1 to 40 carbon atoms which may be substituted with a sulfonic group or a sulfonate group, or an aryl group of 6 to 20 carbon atoms which may be substituted with a sulfonic group or a sulfonate group), an electron accepting dopant substance and a solvent,
wherein the electron accepting dopant substance includes at least one compound selected from the group consisting of arylsulibnic acids of formula (2) below 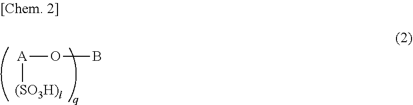
(wherein A is a naphthalene ring or an anthracene ring, B is a perfluorobiphenyl group having a valence of from 2 to 4, the letter “l” is an integer which represents the number of sulfonie groups bonded to A and satisfies the condition 1≤l≤4, and q is an integer from 2 to 4 which represents the number of bonds between B and an oxygen atom) and beteropolyacids.

2. The charge transporting composition of claim 1, wherein the electron accepting dopant substance includes an arylsulfonic acid of formula (2) and a heteropolyacid.

3. The charge transporting composition of claim 1, wherein the heteropolyacid includes at least one compound selected from the group consisting of phosphotungstic acid and phosphomolybdic acid.

4. The charge transporting composition of claim 1, further comprising a surfactant.

5. The charge transporting composition of claim 4, wherein the surfactant is a fluorinated surfactant.

6. The charge transporting composition of claim 1, wherein the solvent includes one or more solvent selected from the group consisting of alcoholic solvents and water.

7. The charge transporting composition of claim 1, for use as a hole collecting layer in an organic photovoltaic device.

8. The charge transporting composition of claim 7, wherein the organic photovoltaic device is an organic thin-film solar cell, a dye-sensitized solar cell or a photosensor.

9. A charge transporting thin film obtained from the charge transporting composition of claim 1.

10. The charge transporting thin film of claim 9 which is a hole collecting layer for an organic photovoltaic device,

11. An electronic device comprising the charge transporting thin film of claim 9.

12. The electronic device of claim 11 which is an organic photovoltaic device.

13. An organic photovoltaic device comprising the hole collecting layer of claim 10 and a non-fullerene active layer provided adjacent thereto.

14. The organic photovoltaic device of claim 13, wherein the non-fullerene active layer includes a polymer having a thiophene skeleton an the main chain.

15. The organic photovoltaic device of claim 13 which is an inverted stack-type device.

16. The organic photovoltaic device of claim 13 which is an organic thin-film solar cell or a photosensor.

17. The organic photovoltaic device of claim 16 which has a top anode structure.
